(19) United States
(12) Patent Application Publication
(10) Pub. No.: US 2026/0371570 A1
(43) Pub. Date: Nov. 19, 2026

(54) SEMICONDUCTOR DEVICE AND METHOD FOR MANUFACTURING THE SAME

(71) Applicant: SK hynix Inc., Gyeonggi-do (KR)

(72) Inventor: Yoon Jae NAM, Gyeonggi-do (KR)

(21) Appl. No.: 19/411,370

(22) Filed: Dec. 8, 2025

(30) Foreign Application Priority Data
May 14, 2025 (KR) 10-2025-0062249

(51) Int. Cl. H10B 12/00

(52) U.S. Cl. CPC H10B 12/485; H10B 12/0335; H10B 12/053; H10B 12/34

(57) ABSTRACT

A semiconductor device includes: wordline structures extending in a first direction, and being spaced apart from each other in a second direction; active regions extending in a diagonal direction forming an acute angle with the first direction, overlapping the wordline structures, and being spaced apart in the first direction; bitline pad regions, each overlapping one end of a corresponding one of the active regions, contacting one side of a corresponding one of the wordline structures, and including a first material; storage-node pad regions, each overlapping another end of the corresponding one of the active regions, contacting another side of the corresponding one of the wordline structures, and including a second material different from the first material; and pad insulation regions, each disposed between a corresponding one of the bitline pad regions and each of the storage-node pad regions, which are spaced apart from each other in the first direction.

### CROSS-REFERENCE TO RELATED APPLICATIONS

This patent document claims the priority and benefits of Korean patent application No. 10-2025-0062249, filed on May 14, 2025, the disclosure of which is incorporated herein by reference in its entirety as part of the disclosure of this patent document.

### TECHNICAL FIELD

Embodiments of the present disclosure generally relate to a semiconductor device and a method for manufacturing the same, and more particularly to a semiconductor device including a plurality of active regions.

### BACKGROUND

A semiconductor device having a memory function among various semiconductor devices may include, as a device that can be used to store information, an array including individual memory cells including transistors. The semiconductor device having a memory function may include, for example, a dynamic random access memory (DRAM). DRAM may include bitlines and wordlines that may cross each other in a vertical direction. The bitlines and wordlines may extend across an array including the memory cells. The bitlines and wordlines can be used to access individual memory cells.

Memory performance, cell stability and reliability, power efficiency, ease of processing, cost, etc. can vary depending on how individual memory cells are designed and placed, and thus research on a cell array design of a memory device and a fabrication process of the cell array is being actively conducted.

### SUMMARY

Various embodiments of the present disclosure relate to a semiconductor device capable of solving the existing problems in which a bridge phenomenon occurs in adjacent active regions and reliability of the semiconductor device deteriorates when wordlines are misaligned in a fabrication process of the semiconductor device.

Various embodiments of the present disclosure relate to a semiconductor device capable of solving the existing problems in which contact resistance increases as a contact region where a bitline contact or a storage-node contact overlap the active regions decreases in size.

In accordance with an embodiment of the present disclosure, a semiconductor device may include: a plurality of wordline structures disposed to extend in a first direction and configured to be spaced apart from each other in a second direction; a plurality of active regions disposed to extend in a diagonal direction forming an acute angle with the first direction, configured to overlap the plurality of wordline structures, and configured to be spaced apart from each other in the first direction; a plurality of bitline pad regions, each of which overlaps one end of a corresponding one of the plurality of active regions, contacts one side of a corresponding one of the plurality of wordline structures, and includes a first material; a plurality of storage-node pad regions, each of which overlaps another end of the corresponding one of the plurality of active regions, contacts another side of the corresponding one of the plurality of wordline structures, and includes a second material different from the first material; and a plurality of pad insulation regions, each of which is disposed between a corresponding one of the plurality of bitline pad regions and each of the plurality of storage-node pad regions which are spaced apart from each other in the first direction.

In some implementations, concentration of impurities included in the first material may

be higher than concentration of impurities included in the second material.

In some implementations, the first material may be polysilicon including impurities; and the second material may be monocrystalline silicon.

In some implementations, a height of each of the plurality of bitline pad regions may be equal to a height of each of the plurality of storage-node pad regions; and a height of each of the plurality of bitline pad regions may be equal to a height of each of the plurality of pad insulation regions.

In some implementations, each of the plurality of bitline pad regions, each of the plurality of storage-node pad regions, and each of the plurality of pad insulation regions may be disposed over a same plane as surfaces of the plurality of active regions.

In some implementations, the second direction may be perpendicular to the first direction; and the second direction may form an acute angle with the diagonal direction.

In some implementations, an angle formed between the diagonal direction and the first direction may be in a range of 30 degrees to 60 degrees.

In some implementations, the semiconductor device may further include: a plurality of bitline contact regions, each of which contacts a top surface of a corresponding one of the plurality of bitline pad regions; a plurality of bitline electrode layers, each of which is disposed over a corresponding one of the plurality of bitline contact regions, overlaps a corresponding one of the plurality of bitline pad regions, and extends in the second direction; a plurality of bitline spacers, each of which contacts both side surfaces of a corresponding one of the plurality of bitline electrode layers and extends in the second direction; and a plurality of storage-node contact regions, each of which contacts a top surface of a corresponding one of the storage-node pad regions.

In some implementations, the plurality of active regions may be further arranged to be

spaced apart from each other in the second direction, and to be spaced apart from each other in the diagonal direction.

In some implementations, the plurality of bitline pad regions may be arranged to be spaced apart from each other in the second direction; and the plurality of storage-node pad regions may be arranged to be spaced apart from each other in the second direction.

In accordance with another embodiment of the present disclosure, a method for manufacturing a semiconductor device may include: forming a plurality of active regions repeatedly spaced apart from each other in a first direction and a second direction, extends in a diagonal direction with respect to the first direction, and is surrounded by a cell isolation region; forming a plurality of first pad regions, each of which overlaps one end of a corresponding one of the plurality of active regions and extends in the second direction; forming a plurality of pad insulation regions, each of which contacts both side surfaces of each of the plurality of first pad regions and extends in the second direction; and forming a plurality of second pad regions that overlaps another end of the corresponding one of the plurality of active regions, extends in the second direction, and is spaced apart from the plurality of first pad regions.

In some implementations, the method may further include: forming an active layer over the plurality of active regions and the cell isolation region, wherein the forming the plurality of first pad regions includes: removing a portion of the active layer.

In some implementations, the method may further include: forming a plurality of filling regions between the plurality of first pad regions, wherein the forming the plurality of pad insulation regions includes: removing a portion of each of the plurality of filling regions.

In some implementations, the method may further include: forming a plurality of wordline structures that overlaps centers of the plurality of active regions, extends in the first direction, and is repeatedly spaced apart from each other in the second direction.

In some implementations, the forming the plurality of wordline structures may include: cutting a portion of each of the plurality of first pad regions, a portion of each of the plurality of second pad regions, and a portion of each of the plurality of pad insulation regions.

In some implementations, the method may further include: forming a plurality of bitline electrode layers that overlaps the plurality of first pad regions and extends in the second direction; and forming a plurality of storage-node contact regions that overlaps the plurality of second pad regions.

In some implementations, the method may further include: forming a plurality of bitline contact regions, each of which is disposed between a corresponding one of the plurality of bitline electrode layers and a corresponding one of the plurality of first pad regions; forming a plurality of bitline spacers, each of which contacts both side surfaces of each of the plurality of bitline electrode layers and extends in the second direction; forming a plurality of bitline capping layers, each of which contacts a top surface of a corresponding one of the plurality of bitline electrode layers; and forming a plurality of contact insulation regions, each of which is disposed between the plurality of storage-node contact regions adjacent to each other in the second direction.

It is to be understood that both the foregoing general description and the following detailed description of the present disclosure are illustrative and explanatory and are intended to provide further explanation of the present disclosure as claimed.

### BRIEF DESCRIPTION OF THE DRAWINGS

The above and other features and beneficial aspects of the present disclosure will become readily apparent with reference to the following detailed description when considered in conjunction with the accompanying drawings.

FIG. 1 is a circuit diagram illustrating an example of a modeling circuit of a unit cell of a semiconductor device according to an embodiment of the present disclosure.

FIG. 2 is a first plan view illustrating an example of a portion of a semiconductor device according to an embodiment of the present disclosure.

FIG. 3 is a second plan view illustrating an example of a portion of a semiconductor device according to an embodiment of the present disclosure.

FIG. 4 is a cross-sectional view illustrating an example structure of the semiconductor device taken along the line A-A’ of FIGS. 2 and 3 according to an embodiment of the present disclosure.

FIG. 5 is a cross-sectional view illustrating an example structure of the semiconductor device taken along the line B-B’ of FIGS. 2 and 3 according to an embodiment of the present disclosure.

FIG. 6 is a cross-sectional view illustrating an example structure of the semiconductor device taken along the line C-C’ of FIGS. 2 and 3 according to an embodiment of the present disclosure.

FIG. 7 is a cross-sectional view illustrating an example structure of the semiconductor device taken along the line D-D’ of FIGS. 2 and 3 according to an embodiment of the present disclosure.

FIG. 8 is a cross-sectional view illustrating an example structure of the semiconductor device taken along the line E-E’ of FIGS. 2 and 3 according to an embodiment of the present disclosure.

FIG. 9 is a flowchart illustrating an example of a method for manufacturing a semiconductor device according to an embodiment of the present disclosure.

FIG. 10A is a plan view illustrating an example result of performing operation S10 of

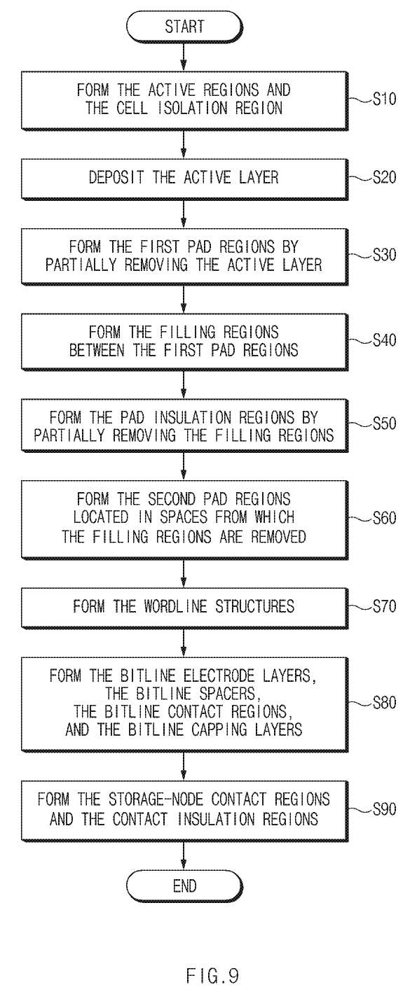

FIG. 9 according to an embodiment of the present disclosure.

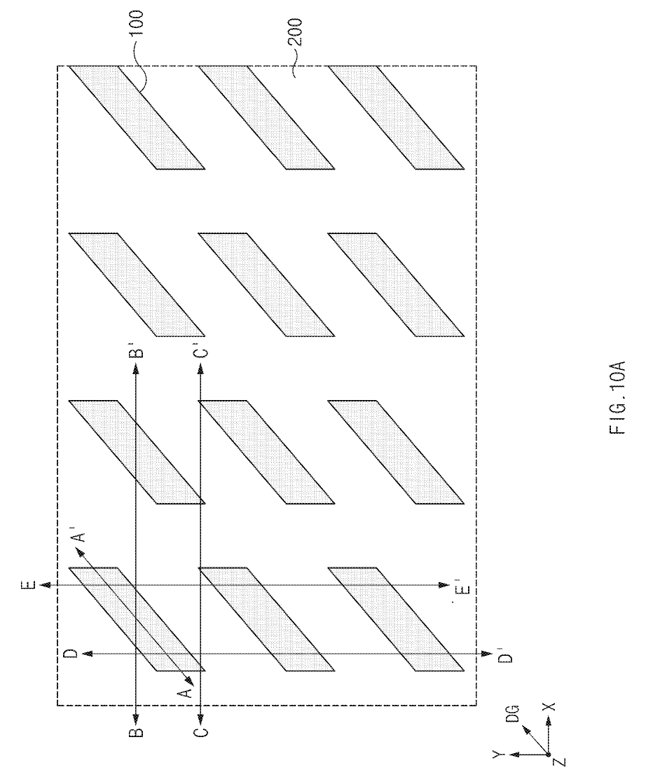

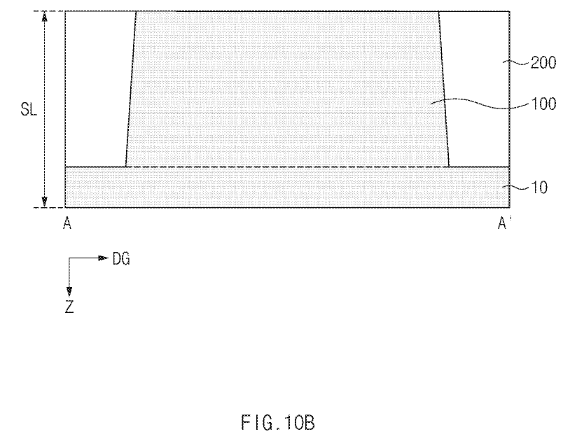

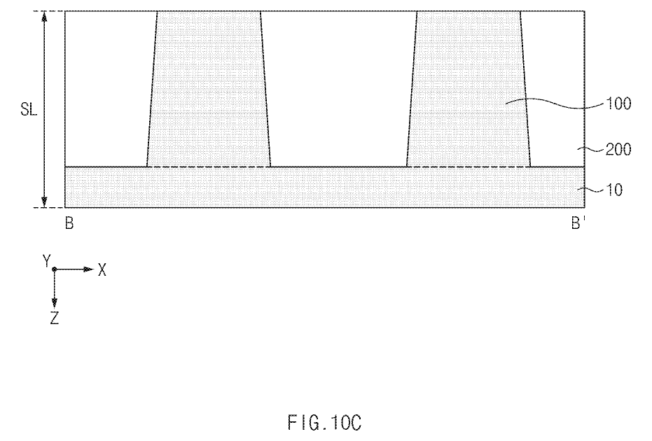

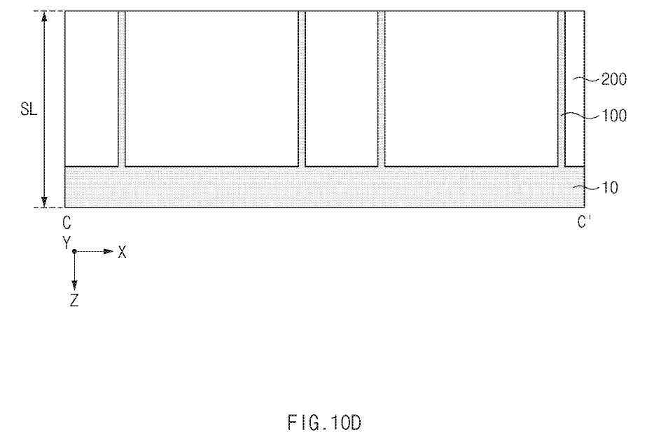

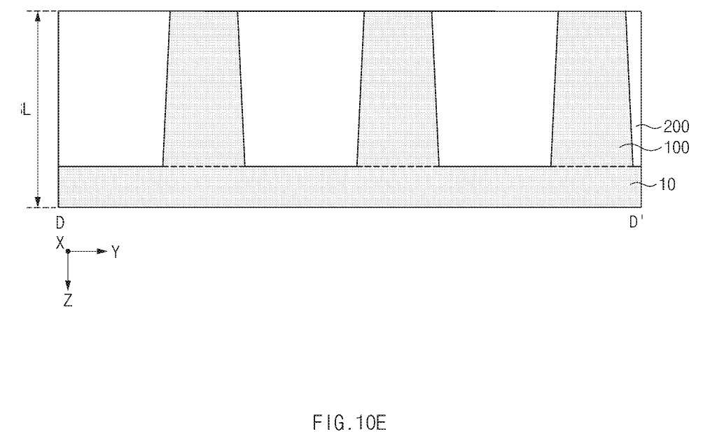

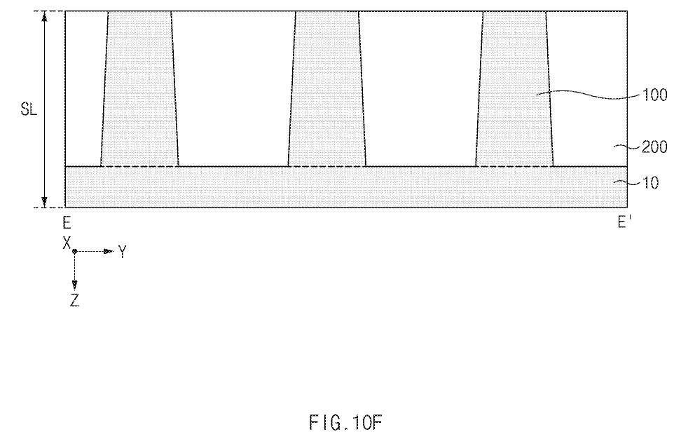

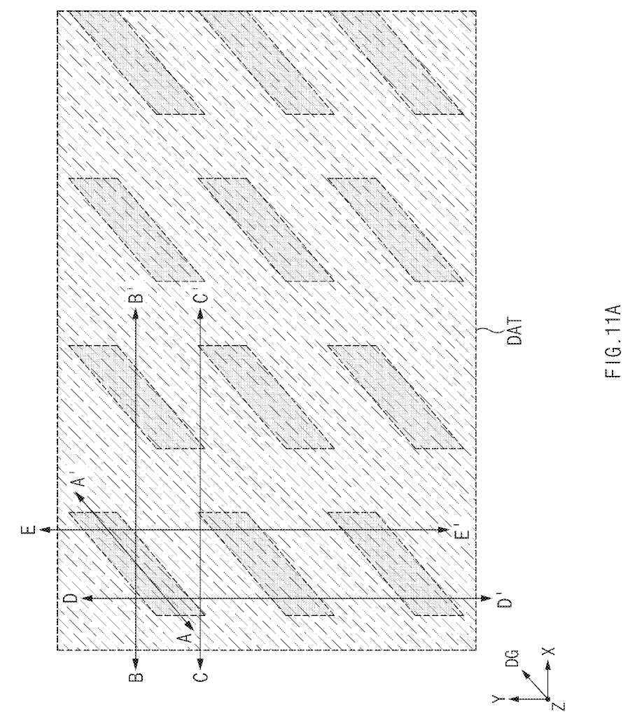

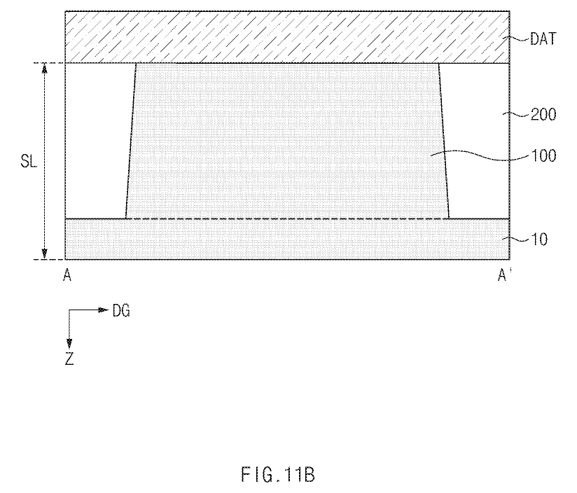

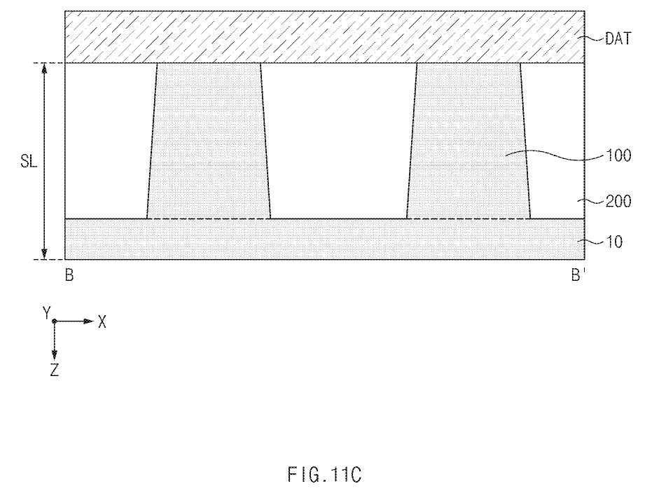

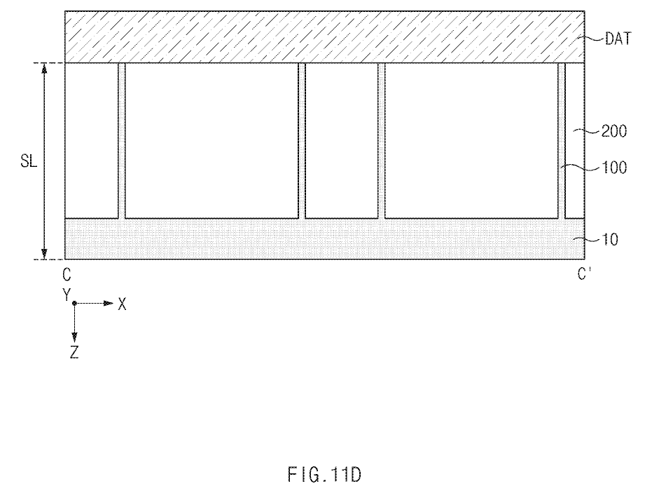

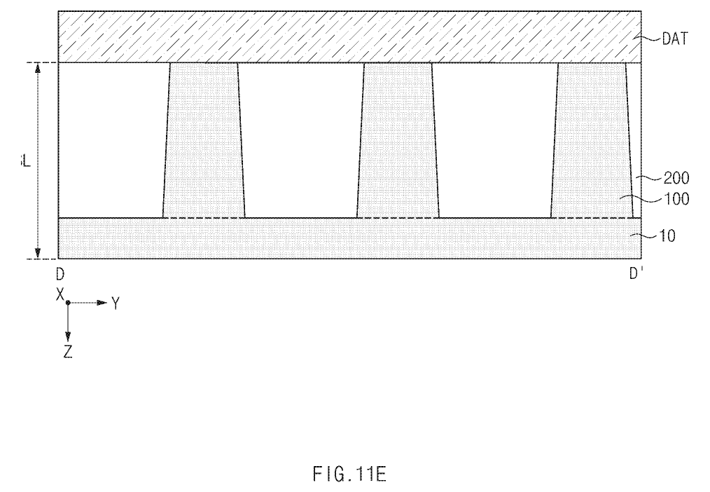

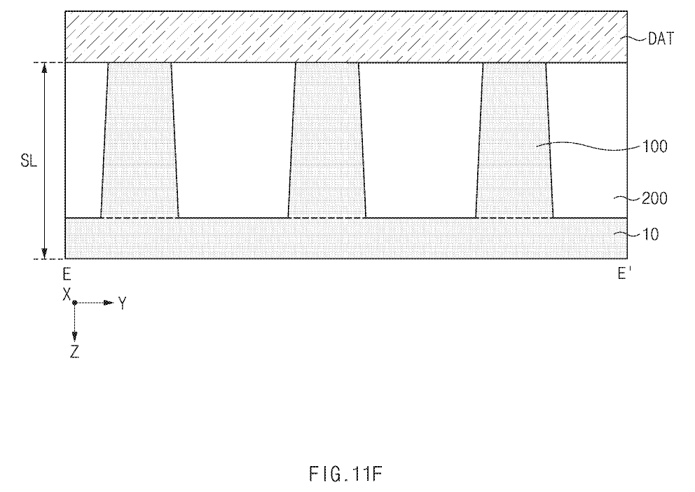

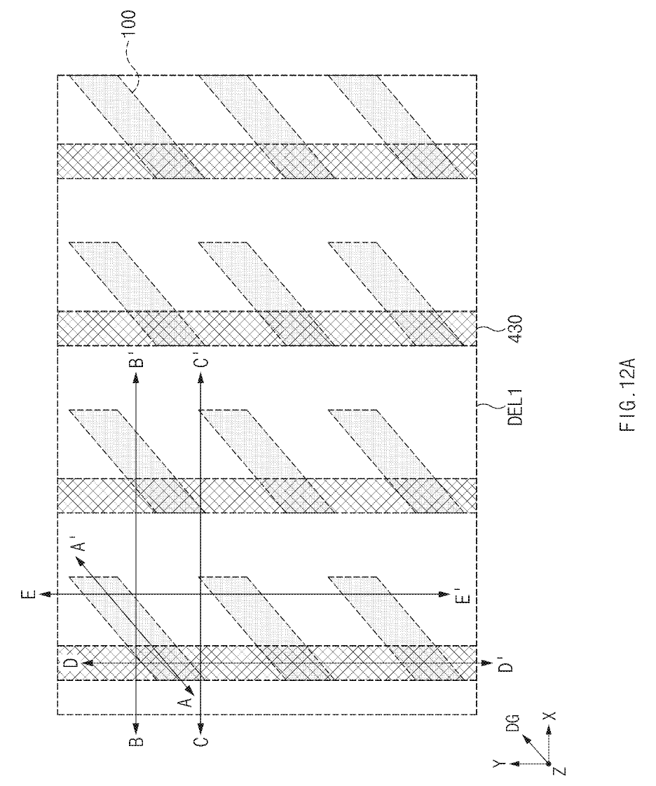

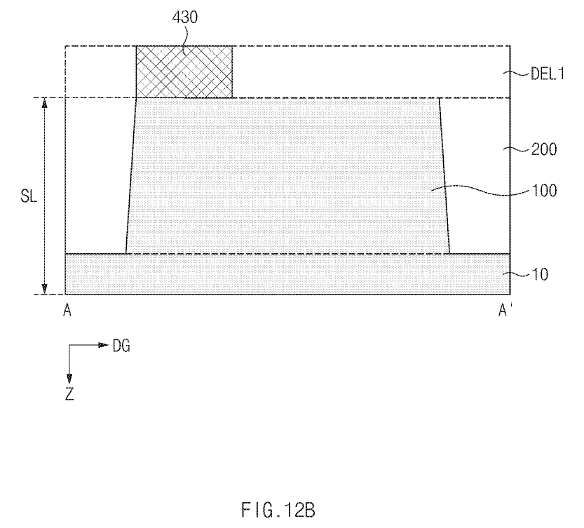

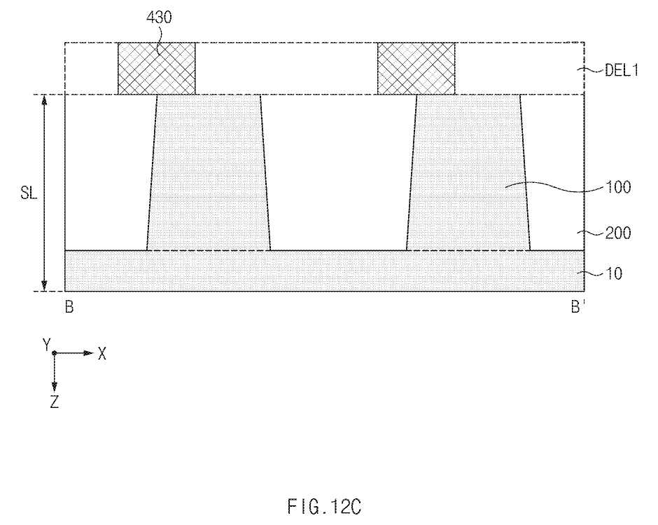

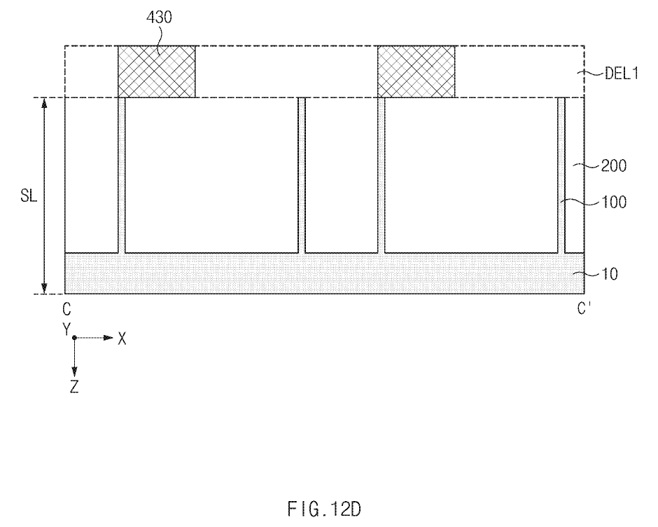

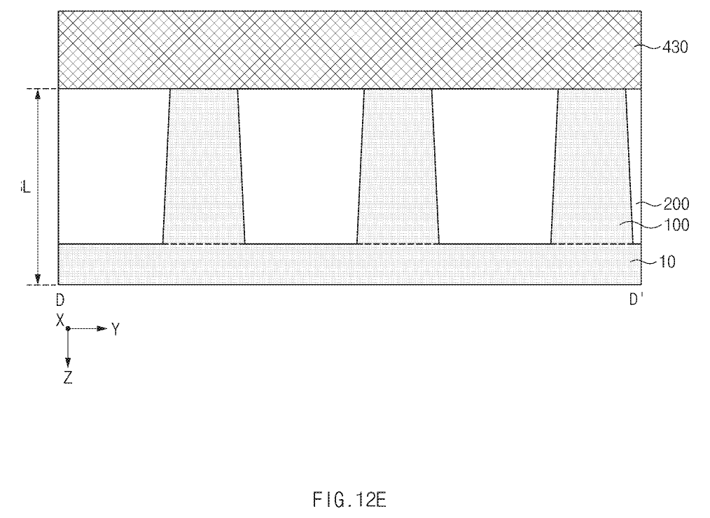

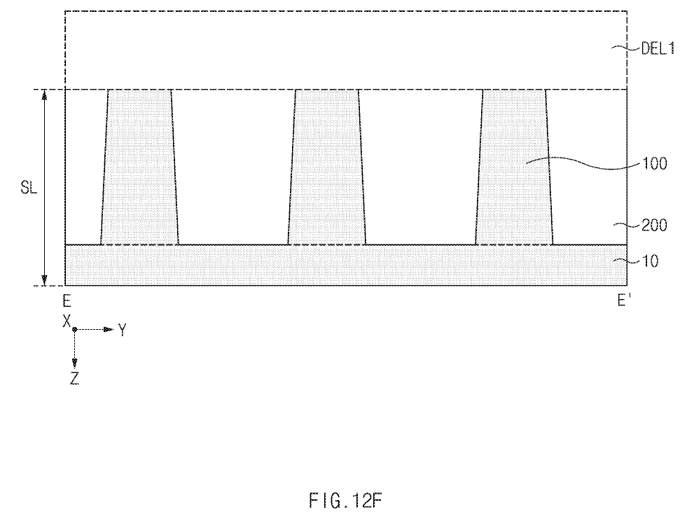

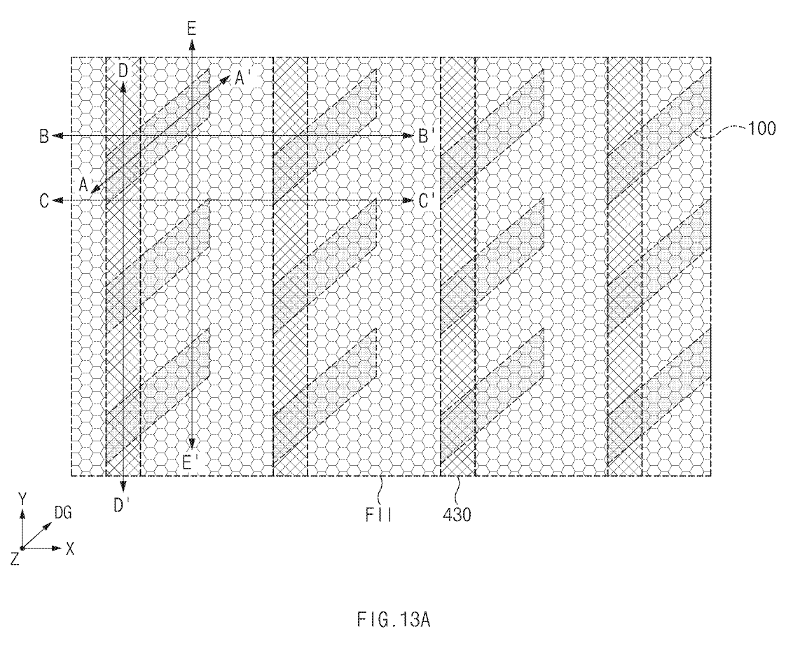

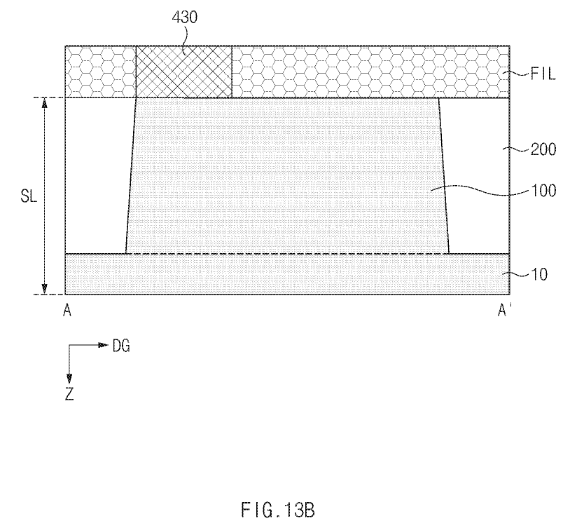

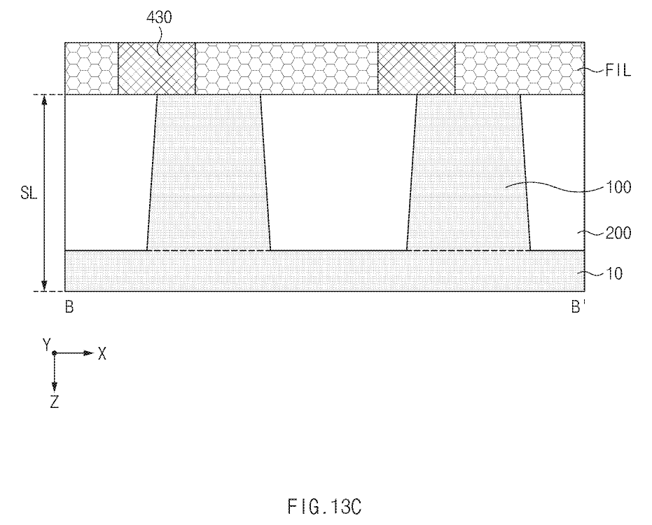

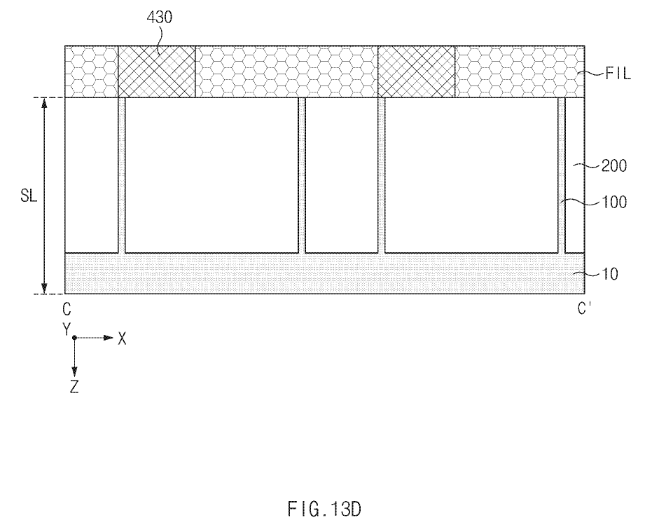

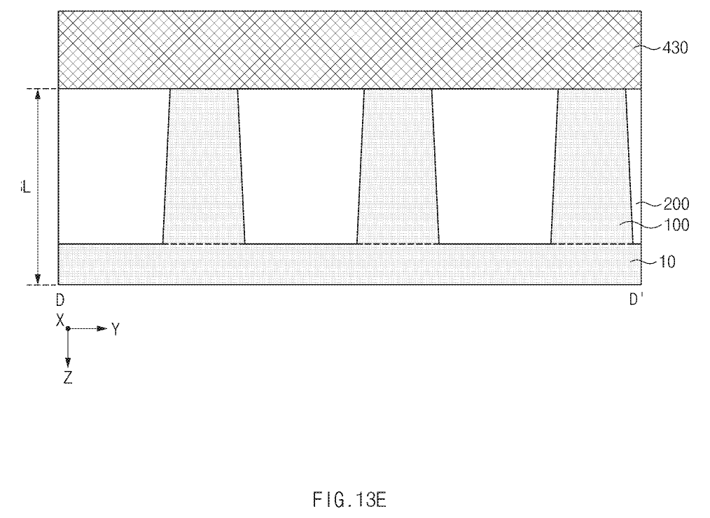

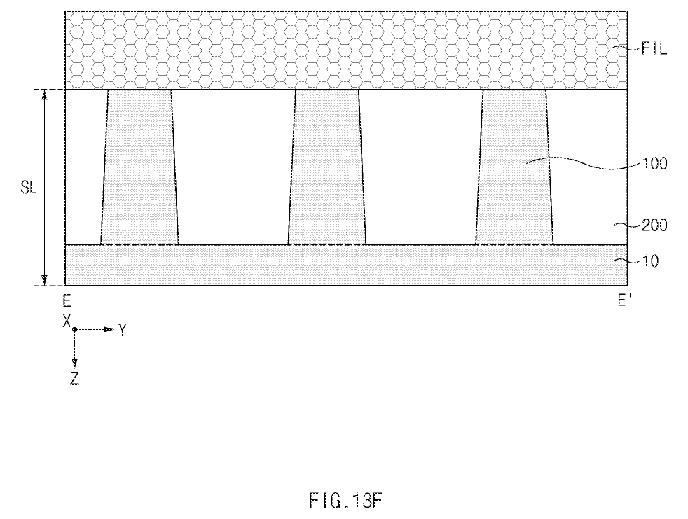

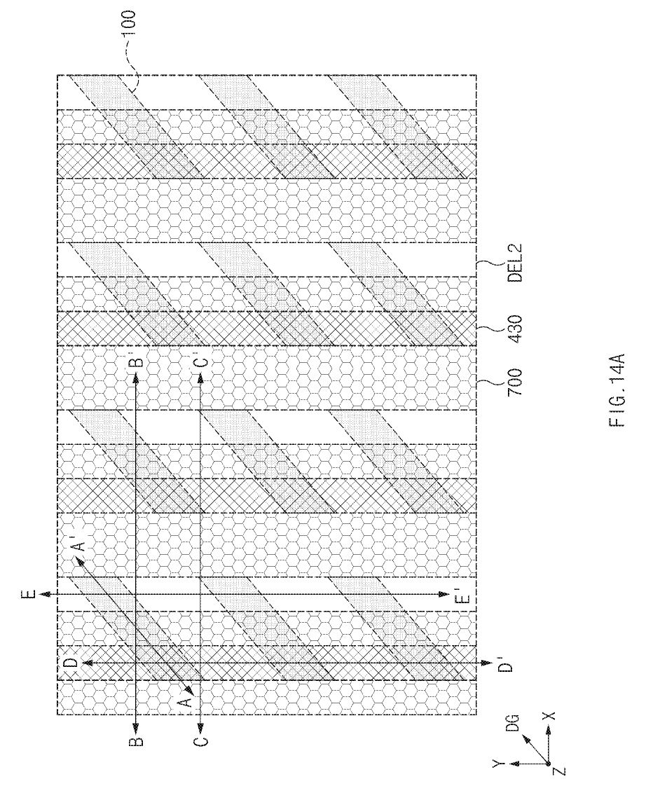

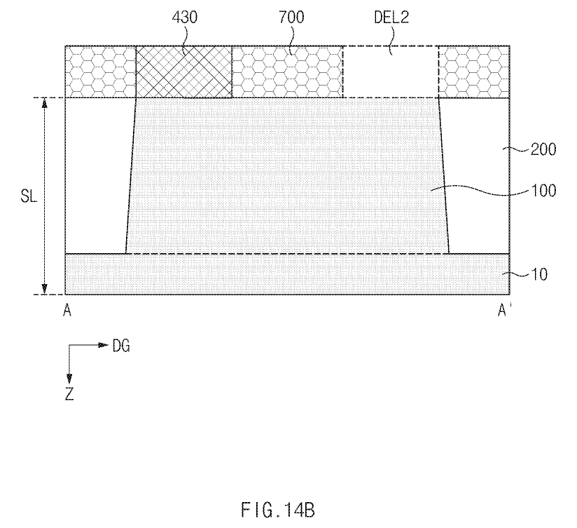

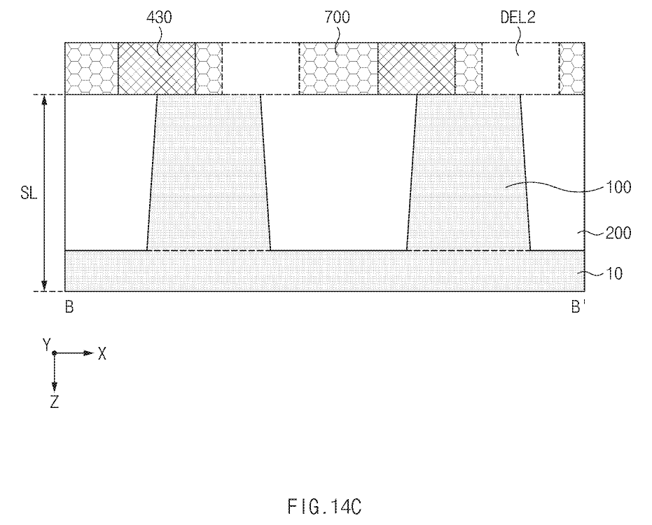

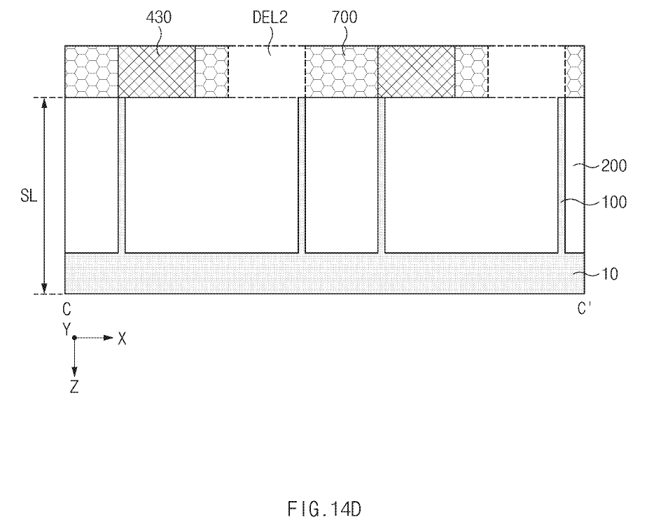

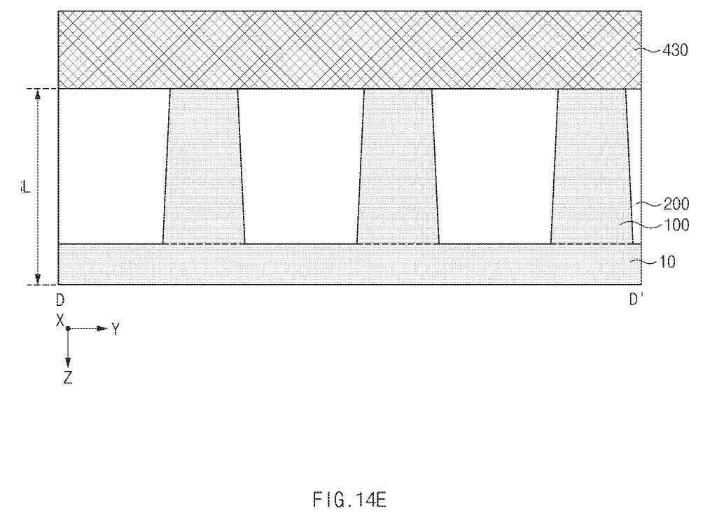

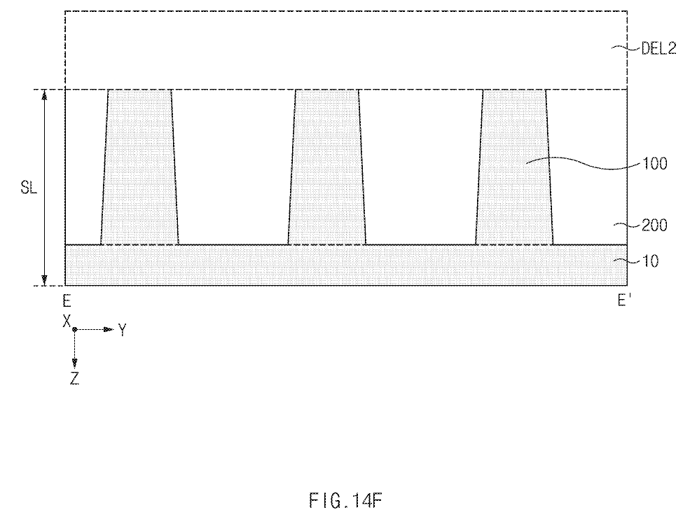

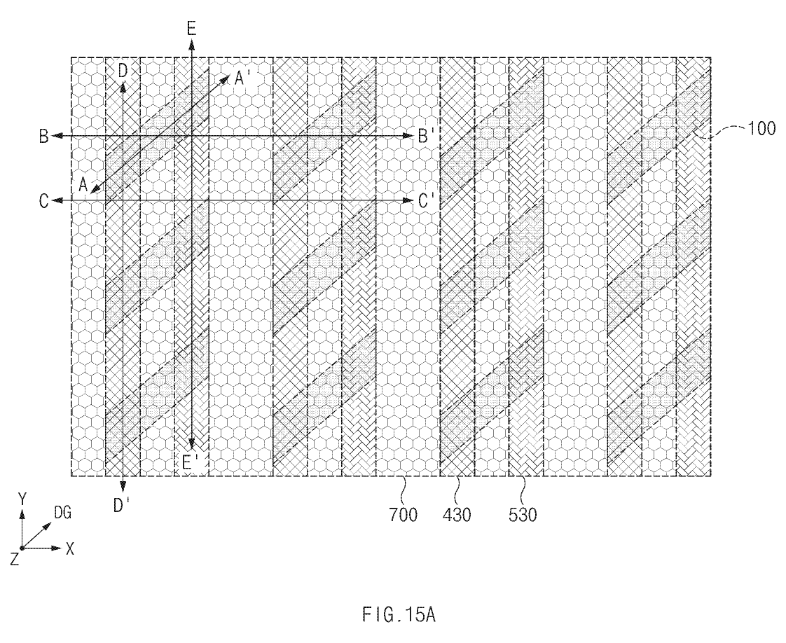

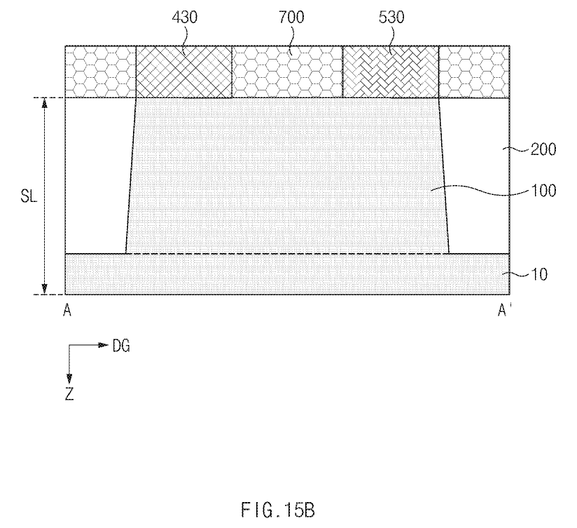

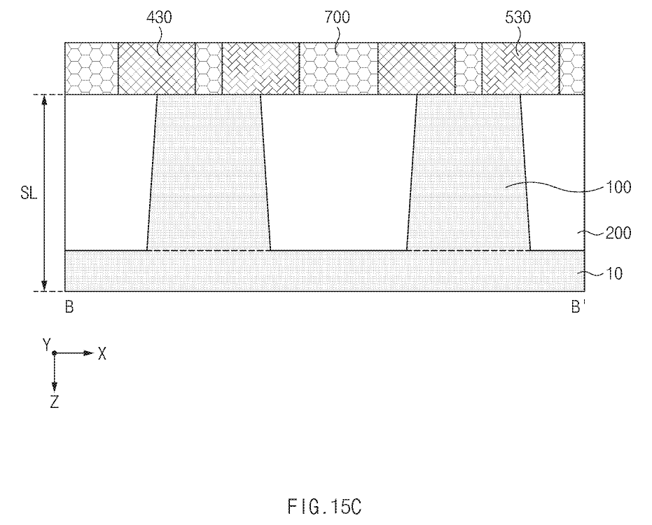

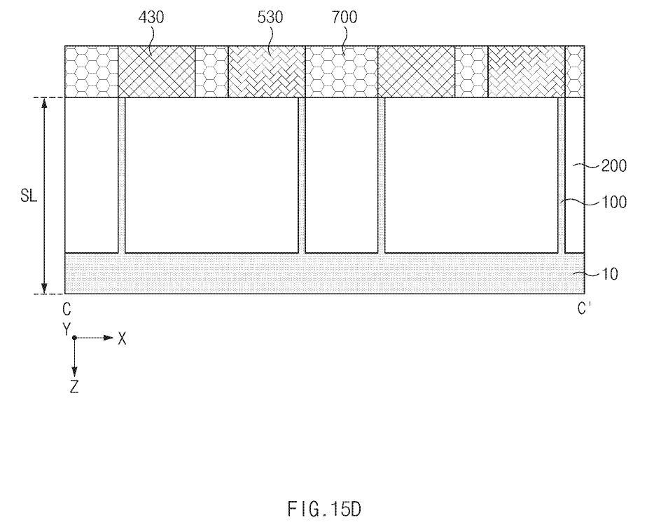

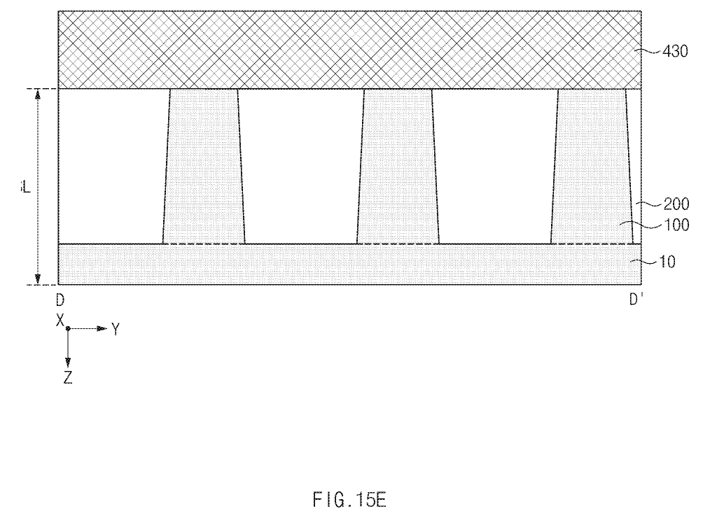

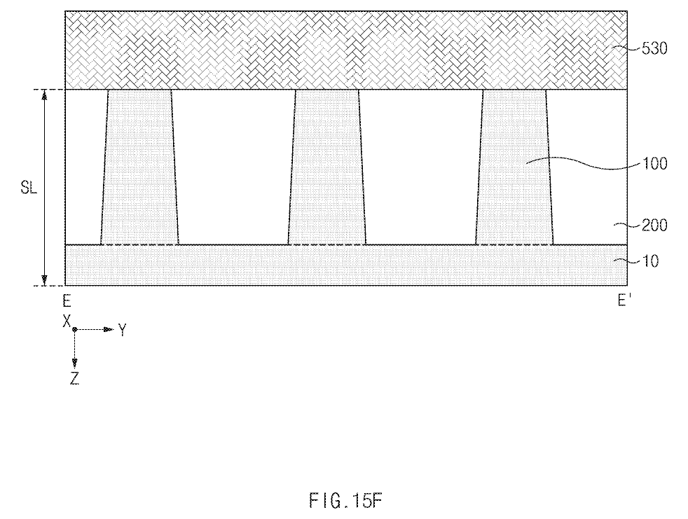

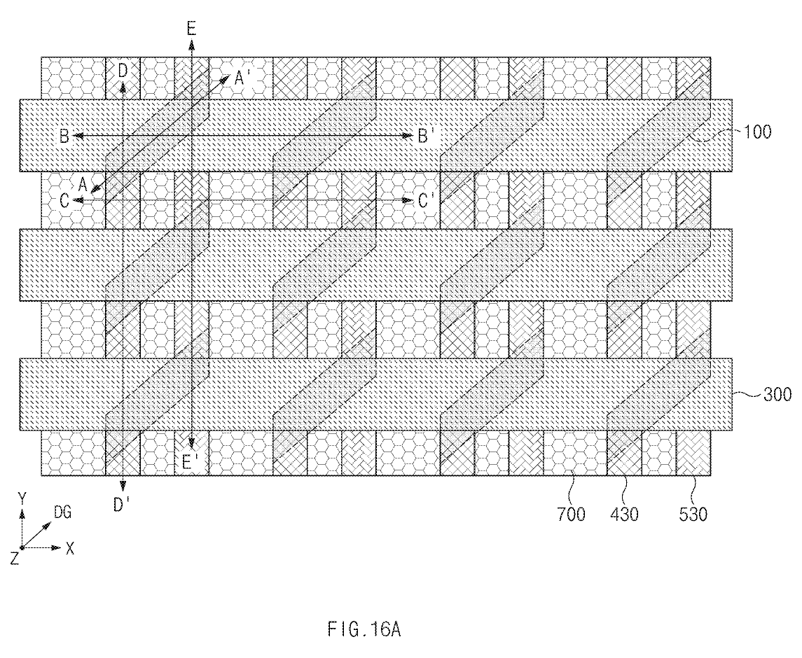

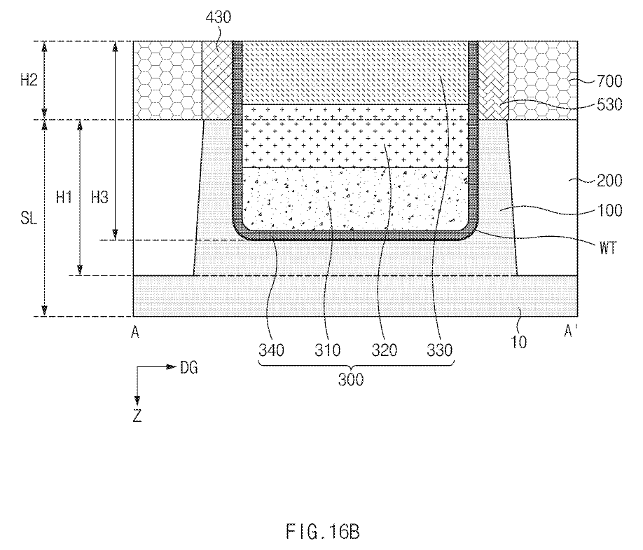

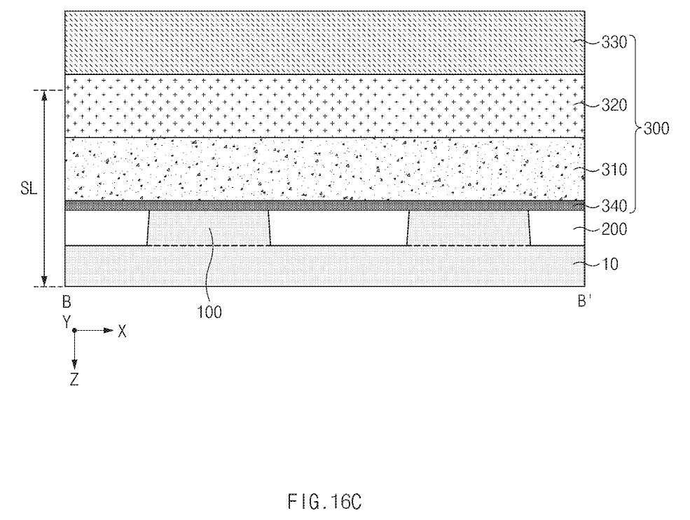

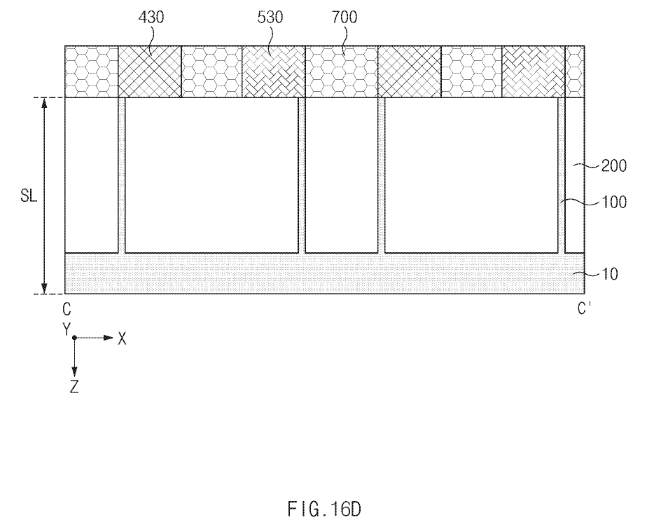

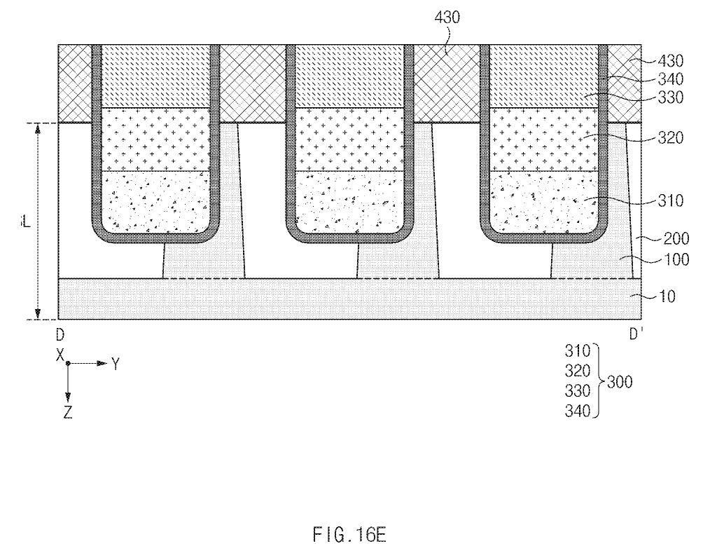

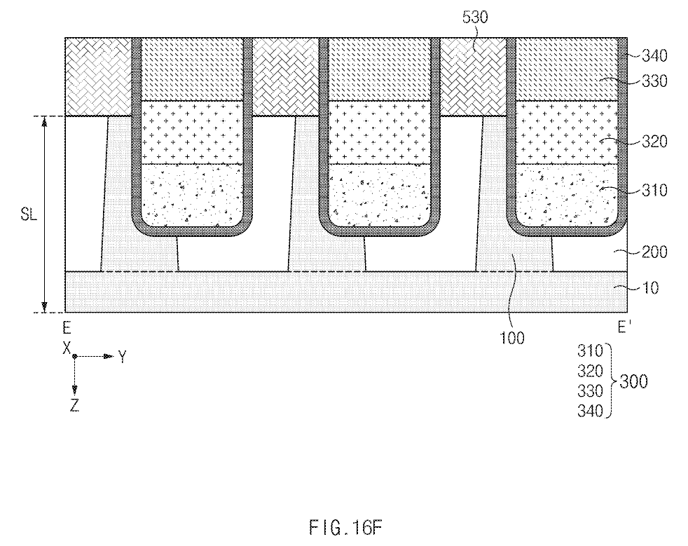

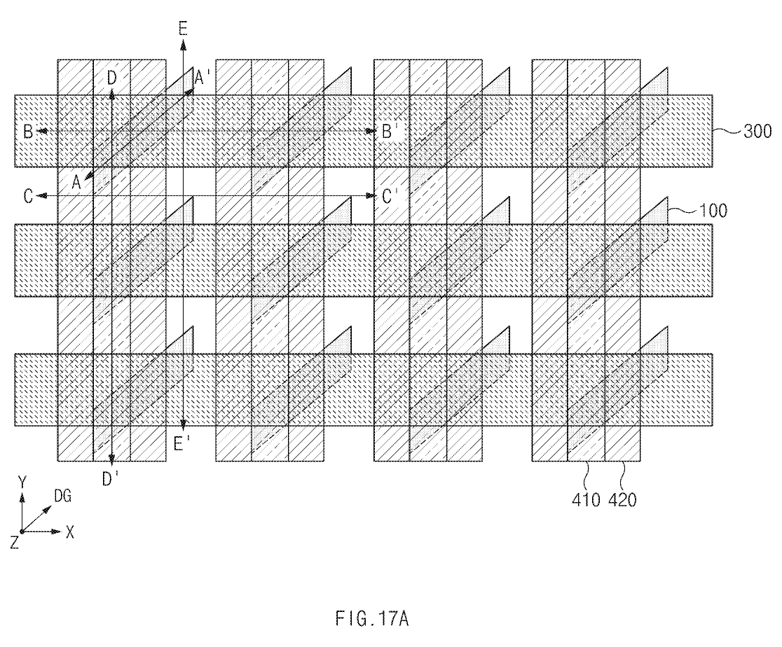

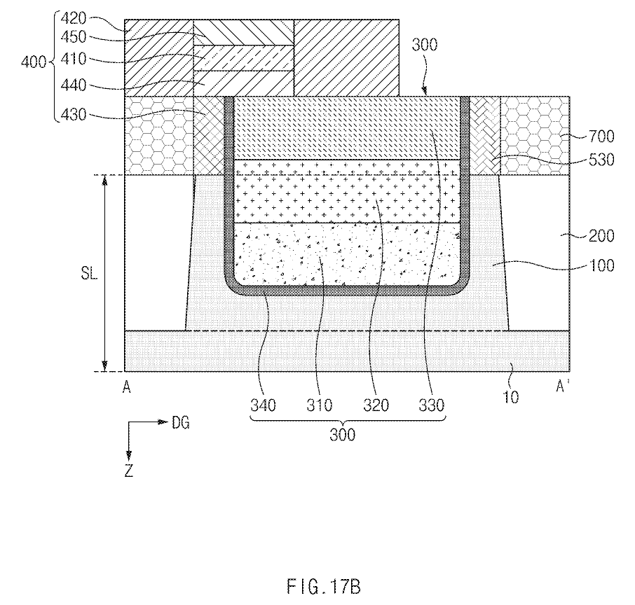

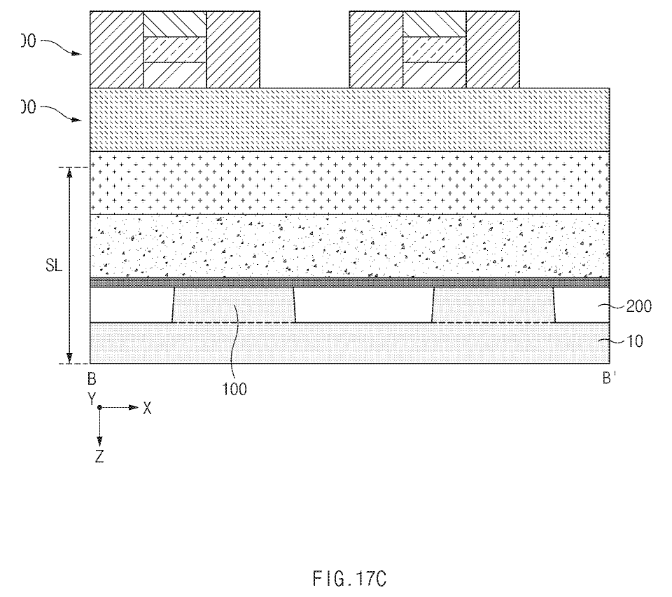

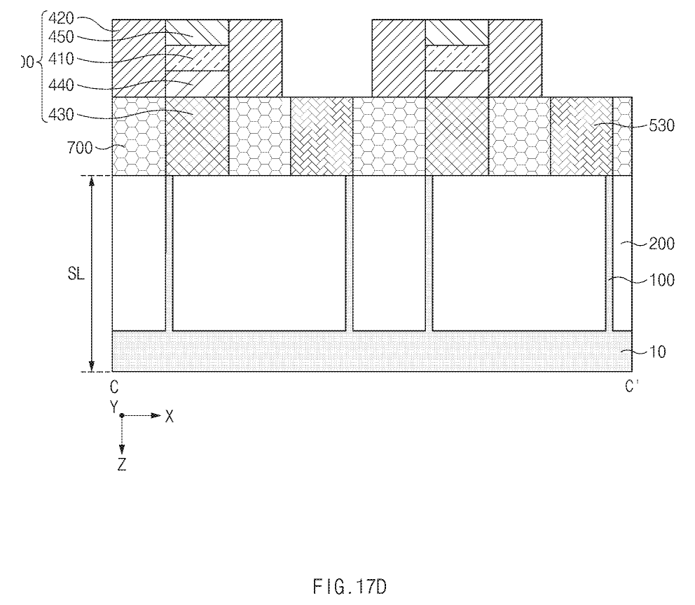

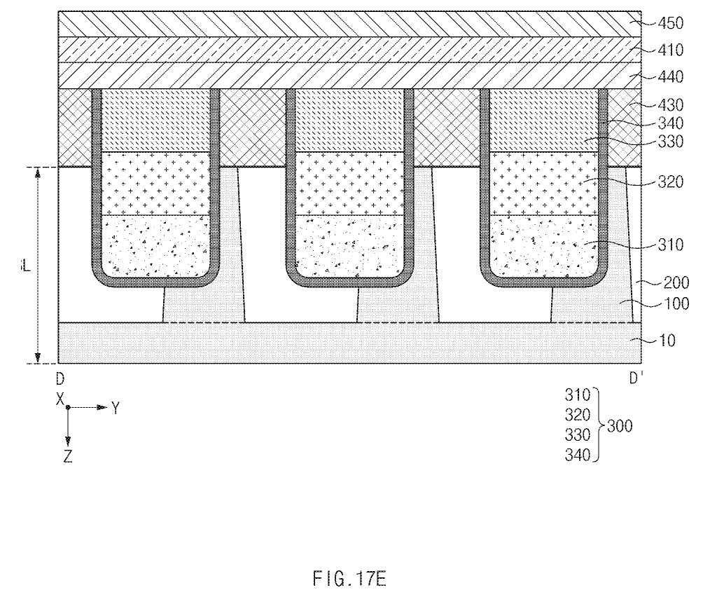

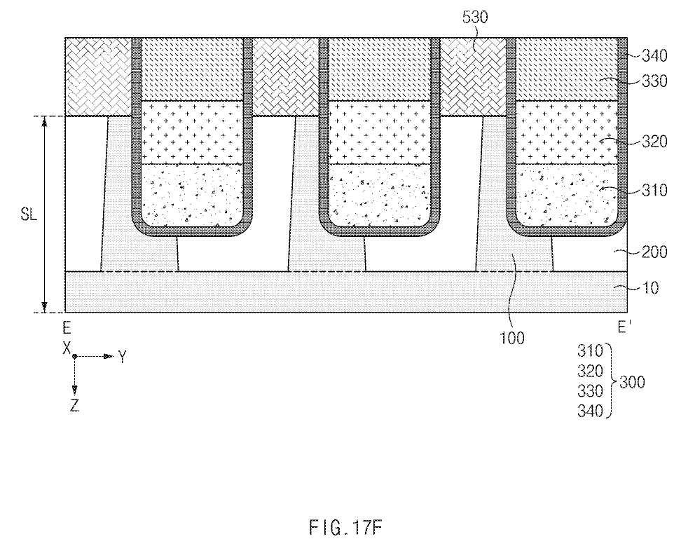

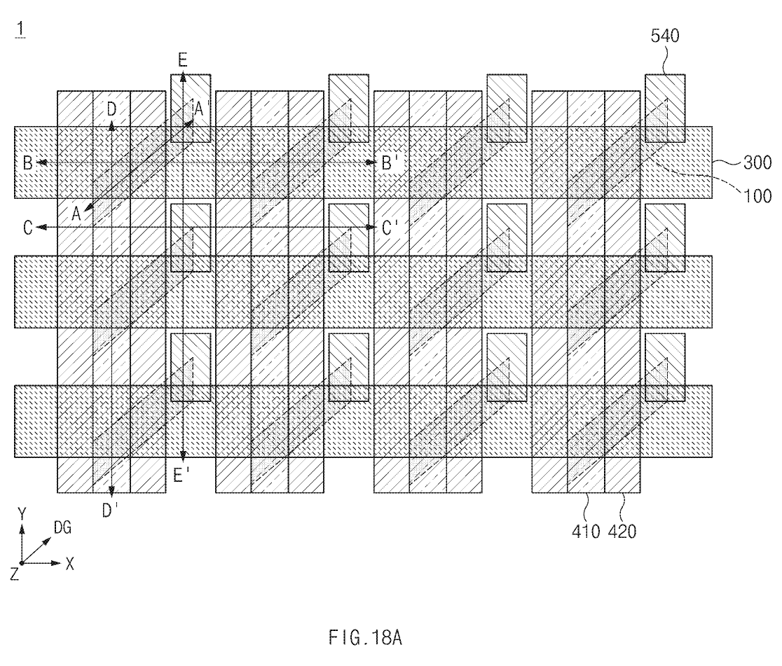

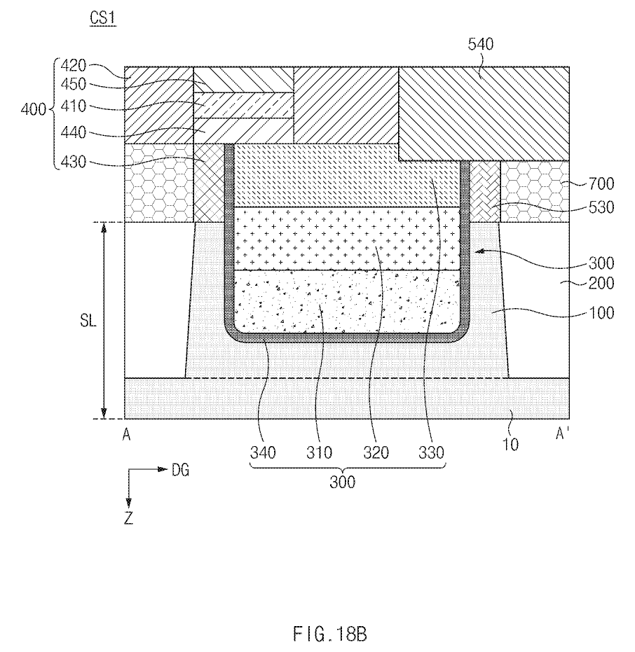

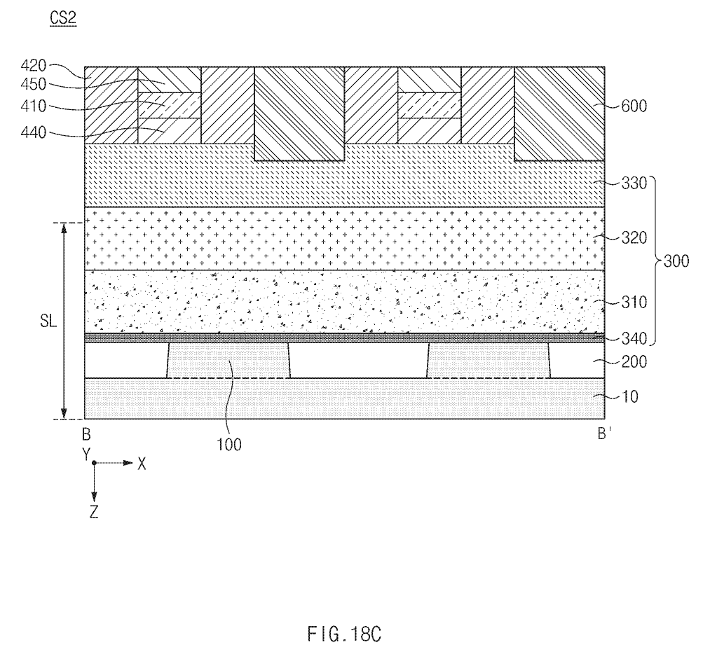

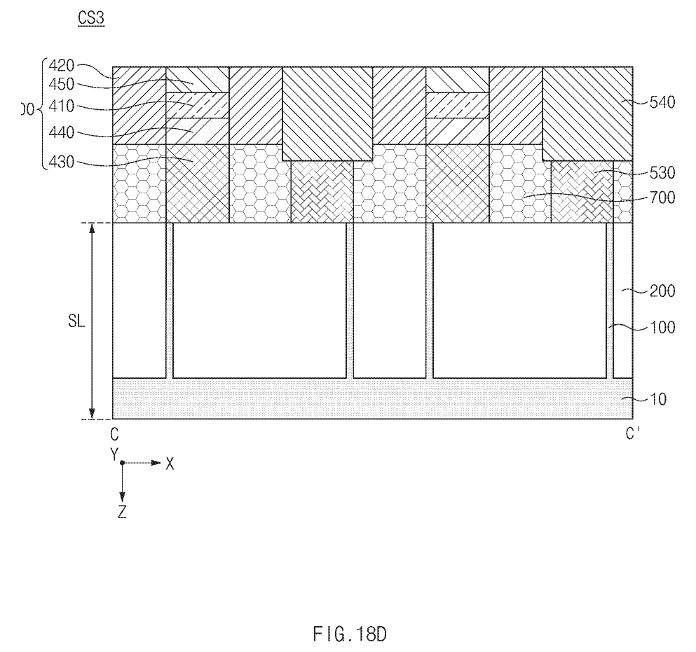

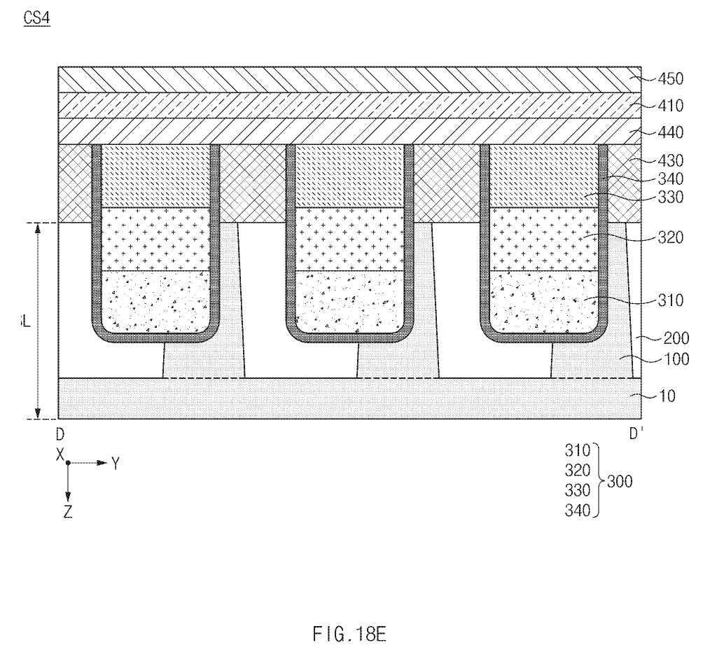

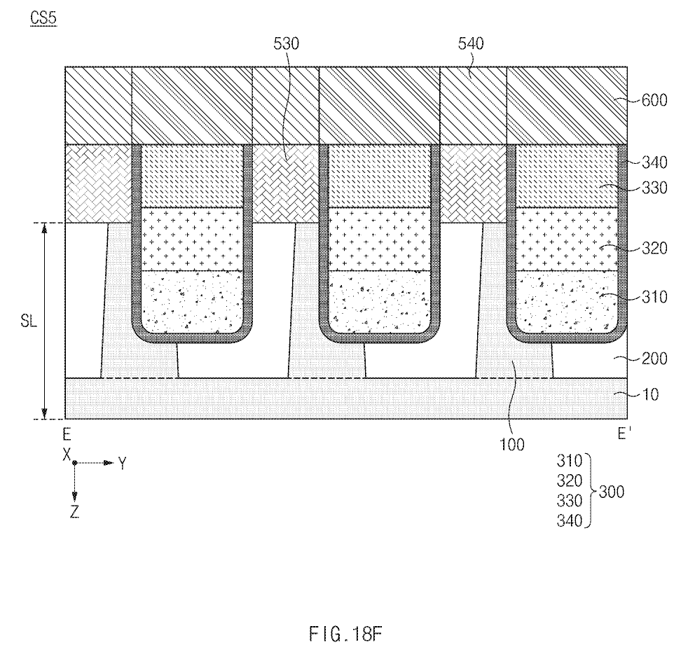

FIG. 10B is a cross-sectional view illustrating an example structure of the semiconductor device taken along the line A-A’ of FIG. 10A according to an embodiment of the present disclosure.

FIG. 10C is a cross-sectional view illustrating an example structure of the semiconductor device taken along the line B-B’ of FIG. 10A according to an embodiment of the present disclosure.

FIG. 10D is a cross-sectional view illustrating an example structure of the semiconductor device taken along the line C-C’ of FIG. 10A according to an embodiment of the present disclosure.

FIG. 10E is a cross-sectional view illustrating an example structure of the semiconductor device taken along the line D-D’ of FIG. 10A according to an embodiment of the present disclosure.

FIG. 10F is a cross-sectional view illustrating an example structure of the semiconductor device taken along the line E-E’ of FIG. 10A according to an embodiment of the present disclosure.

FIG. 11A is a plan view illustrating an example result of performing operation S20 of FIG. 9 according to an embodiment of the present disclosure.

FIG. 11B is a cross-sectional view illustrating an example structure of the semiconductor device taken along the line A-A’ of FIG. 11A according to an embodiment of the present disclosure.

FIG. 11C is a cross-sectional view illustrating an example structure of the semiconductor device taken along the line B-B’ of FIG. 11A according to an embodiment of the present disclosure.

FIG. 11D is a cross-sectional view illustrating an example structure of the semiconductor device taken along the line C-C’ of FIG. 11A according to an embodiment of the present disclosure.

FIG. 11E is a cross-sectional view illustrating an example structure of the semiconductor device taken along the line D-D’ of FIG. 11A according to an embodiment of the present disclosure.

FIG. 11F is a cross-sectional view illustrating an example structure of the semiconductor device taken along the line E-E’ of FIG. 11A according to an embodiment of the present disclosure.

FIG. 12A is a plan view illustrating an example result of performing operation S30 of FIG. 9 according to an embodiment of the present disclosure.

FIG. 12B is a cross-sectional view illustrating an example structure of the semiconductor device taken along the line A-A’ of FIG. 12A according to an embodiment of the present disclosure.

FIG. 12C is a cross-sectional view illustrating an example structure of the semiconductor device taken along the line B-B’ of FIG. 12A according to an embodiment of the present disclosure.

FIG. 12D is a cross-sectional view illustrating an example structure of the semiconductor device taken along the line C-C’ of FIG. 12A according to an embodiment of the present disclosure.

FIG. 12E is a cross-sectional view illustrating an example structure of the semiconductor device taken along the line D-D’ of FIG. 12A according to an embodiment of the present disclosure.

FIG. 12F is a cross-sectional view illustrating an example structure of the

semiconductor device taken along the line E-E’ of FIG. 12A according to an embodiment of the present disclosure.

FIG. 13A is a plan view illustrating an example result of performing operation S40 of FIG. 9 according to an embodiment of the present disclosure.

FIG. 13B is a cross-sectional view illustrating an example structure of the semiconductor device taken along the line A-A’ of FIG. 13A according to an embodiment of the present disclosure.

FIG. 13C is a cross-sectional view illustrating an example structure of the semiconductor device taken along the line B-B’ of FIG. 13A according to an embodiment of the present disclosure.

FIG. 13D is a cross-sectional view illustrating an example structure of the semiconductor device taken along the line C-C’ of FIG. 13A according to an embodiment of the present disclosure.

FIG. 13E is a cross-sectional view illustrating an example structure of the semiconductor device taken along the line D-D’ of FIG. 13A according to an embodiment of the present disclosure.

FIG. 13F is a cross-sectional view illustrating an example structure of the semiconductor device taken along the line E-E’ of FIG. 13A according to an embodiment of the present disclosure.

FIG. 14A is a plan view illustrating an example result of performing operation S50 of FIG. 9 according to an embodiment of the present disclosure.

FIG. 14B is a cross-sectional view illustrating an example structure of the semiconductor device taken along the line A-A’ of FIG. 14A according to an embodiment of the present disclosure.

FIG. 14C is a cross-sectional view illustrating an example structure of the semiconductor device taken along the line B-B’ of FIG. 14A according to an embodiment of the present disclosure.

FIG. 14D is a cross-sectional view illustrating an example structure of the semiconductor device taken along the line C-C’ of FIG. 14A according to an embodiment of the present disclosure.

FIG. 14E is a cross-sectional view illustrating an example structure of the semiconductor device taken along the line D-D’ of FIG. 14A according to an embodiment of the present disclosure.

FIG. 14F is a cross-sectional view illustrating an example structure of the semiconductor device taken along the line E-E’ of FIG. 14A according to an embodiment of the present disclosure.

FIG. 15A is a plan view illustrating an example result of performing operation S60 of FIG. 9 according to an embodiment of the present disclosure.

FIG. 15B is a cross-sectional view illustrating an example structure of the semiconductor device taken along the line A-A’ of FIG. 15A according to an embodiment of the present disclosure.

FIG. 15C is a cross-sectional view illustrating an example structure of the semiconductor device taken along the line B-B’ of FIG. 15A according to an embodiment of the present disclosure.

FIG. 15D is a cross-sectional view illustrating an example structure of the semiconductor device taken along the line C-C’ of FIG. 15A according to an embodiment of the present disclosure.

FIG. 15E is a cross-sectional view illustrating an example structure of the

semiconductor device taken along the line D-D’ of FIG. 15A according to an embodiment of the present disclosure.

FIG. 15F is a cross-sectional view illustrating an example structure of the semiconductor device taken along the line E-E’ of FIG. 15A according to an embodiment of the present disclosure.

FIG. 16A is a plan view illustrating an example result of performing operation S70 of FIG. 9 according to an embodiment of the present disclosure.

FIG. 16B is a cross-sectional view illustrating an example structure of the semiconductor device taken along the line A-A’ of FIG. 16A according to an embodiment of the present disclosure.

FIG. 16C is a cross-sectional view illustrating an example structure of the semiconductor device taken along the line B-B’ of FIG. 16A according to an embodiment of the present disclosure.

FIG. 16D is a cross-sectional view illustrating an example structure of the semiconductor device taken along the line C-C’ of FIG. 16A according to an embodiment of the present disclosure.

FIG. 16E is a cross-sectional view illustrating an example structure of the semiconductor device taken along the line D-D’ of FIG. 16A according to an embodiment of the present disclosure.

FIG. 16F is a cross-sectional view illustrating an example structure of the semiconductor device taken along the line E-E’ of FIG. 16A according to an embodiment of the present disclosure.

FIG. 17A is a plan view illustrating an example result of performing operation S80 of FIG. 9 according to an embodiment of the present disclosure.

FIG. 17B is a cross-sectional view illustrating an example structure of the semiconductor device taken along the line A-A’ of FIG. 17A according to an embodiment of the present disclosure.

FIG. 17C is a cross-sectional view illustrating an example structure of the semiconductor device taken along the line B-B’ of FIG. 17A according to an embodiment of the present disclosure.

FIG. 17D is a cross-sectional view illustrating an example structure of the semiconductor device taken along the line C-C’ of FIG. 17A according to an embodiment of the present disclosure.

FIG. 17E is a cross-sectional view illustrating an example structure of the semiconductor device taken along the line D-D’ of FIG. 17A according to an embodiment of the present disclosure.

FIG. 17F is a cross-sectional view illustrating an example structure of the semiconductor device taken along the line E-E’ of FIG. 17A according to an embodiment of the present disclosure.

FIG. 18A is a plan view illustrating an example result of performing operation S90 of FIG. 9 according to an embodiment of the present disclosure.

FIG. 18B is a cross-sectional view illustrating an example structure of the semiconductor device taken along the line A-A’ of FIG. 18A according to an embodiment of the present disclosure.

FIG. 18C is a cross-sectional view illustrating an example structure of the semiconductor device taken along the line B-B’ of FIG. 18A according to an embodiment of the present disclosure.

FIG. 18D is a cross-sectional view illustrating an example structure of the

semiconductor device taken along the line C-C’ of FIG. 18A according to an embodiment of the present disclosure.

FIG. 18E is a cross-sectional view illustrating an example structure of the semiconductor device taken along the line D-D’ of FIG. 18A according to an embodiment of the present disclosure.

FIG. 18F is a cross-sectional view illustrating an example structure of the semiconductor device taken along the line E-E’ of FIG. 18A according to an embodiment of the present disclosure.

### DETAILED DESCRIPTION

The present disclosure provides embodiments and examples of a semiconductor device including a plurality of active regions and a method for manufacturing the same that may be used in configurations to substantially address one or more technical or engineering issues and to mitigate limitations or disadvantages encountered in some semiconductor devices in the art. Some embodiments of the present disclosure relate to a semiconductor device capable of solving the existing problems in which a bridge phenomenon occurs in adjacent active regions and reliability of the semiconductor device deteriorates when wordlines are misaligned in a fabrication process of the semiconductor device. Some embodiments of the present disclosure relate to a semiconductor device capable of solving the existing problems in which contact resistance increases as a contact region where a bitline contact or a storage-node contact overlap the active regions decreases in size. In recognition of the issues above, the present disclosure may provide a semiconductor device in which the bridge phenomenon that may occur between adjacent active regions is prevented. The present disclosure may provide a semiconductor device with improved operating speed and reduced leakage. The present

disclosure may provide a semiconductor device in which process complexity is reduced by forming a relatively shallow cell isolation region for defining active regions.

Reference will now be made in detail to the embodiments of the present disclosure, examples of which are illustrated in the accompanying drawings. Wherever possible, the same reference numbers will be used throughout the drawings to refer to the same or like parts. While the present disclosure is susceptible to various modifications and alternative forms, specific embodiments thereof are shown by way of example in the drawings. However, the present disclosure should not be construed as being limited to the embodiments set forth herein.

Hereinafter, various embodiments will be described with reference to the accompanying drawings. However, it should be understood that the present disclosure is not limited to specific embodiments, but includes various modifications, equivalents and/or alternatives of the embodiments. The embodiments of the present disclosure may provide a variety of effects capable of being directly or indirectly recognized through the present disclosure.

In describing the components of the embodiments of the present disclosure, various terms such as first, second, etc., may be used solely for the purpose of differentiating one component from another, but the essence, order, and sequence of the components are not limited to these terms. Unless defined otherwise, all terms, including technical and scientific terms, used in the present disclosure may have the same meaning as commonly understood by a person having ordinary skill in the art to which the present disclosure pertains. It will be further understood that terms, such as those defined in commonly used dictionaries, may be interpreted as having a meaning that is consistent with their meaning in the context of the related art and the present disclosure, and should not be interpreted in an idealized or overly formal sense unless expressly so defined herein.

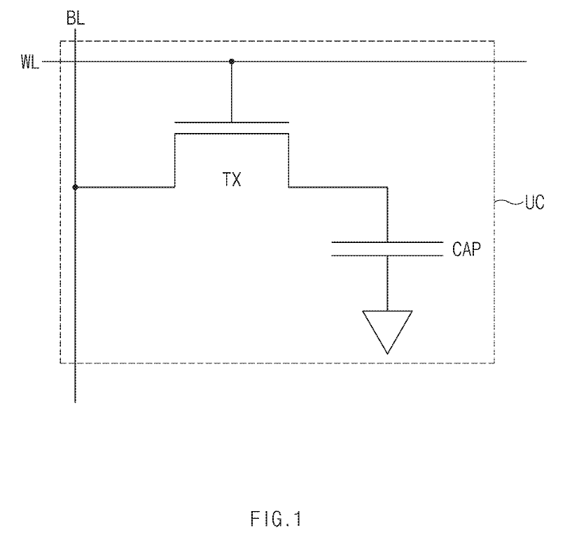

FIG. 1 is a circuit diagram illustrating a modeling circuit of a unit cell (UC) of a

semiconductor device according to an embodiment of the present disclosure.

Referring to FIG. 1, the unit cell (UC) of the semiconductor device according to an embodiment of the present disclosure may include a transistor (TX) and a capacitor (CAP). The unit cell (UC) may be a unit that stores data in the semiconductor device. The semiconductor device according to an embodiment of the present disclosure may function as a data storage device that may be included in various electronic devices such as computers. In some implementations, the semiconductor device may be a volatile memory device (e.g., a dynamic random access memory (DRAM)) or a non-volatile memory device (e.g., a NAND memory).

The transistor (TX) may be a switching element between a bitline (BL) and a capacitor (CAP). The transistor (TX) may be, for example, a metal oxide semiconductor field effect transistor (MOSFET). The transistor (TX) may operate with an electric field generated by a voltage applied to a gate terminal thereof. When the transistor (TX) is turned on, the bitline (BL) and the capacitor (CAP) may be electrically connected to each other. When the transistor (TX) is turned off, electrical connection between the bitline (BL) and the capacitor (CAP) may be prevented.

The wordline (WL) may adjust (control) on/off states of the transistor (TX). For example, when a wordline signal applied to the wordline (WL) has a logic high level, the transistor (TX) may be turned on. On the other hand, when the wordline signal applied to the wordline (WL) has a logic low level, the transistor (TX) may be turned off.

The bitline (BL) may be an interconnect structure designed to transmit data. The bitline (BL) may transfer charges to the capacitor (CAP) when the transistor (TX) is turned on. When the bitline signal applied to the bitline (BL) has a high level and the transistor (TX) is turned on, data “1” may be stored in the capacitor (CAP). When the bitline signal applied to

the bitline (BL) has a low level and the transistor (TX) is turned on, data “0” may be stored in the capacitor (CAP).

A capacitor (CAP) may be a storage device that stores data. For example, the second capacitor (CAP) may include at least one of a Metal-Insulator-Metal (MIM) capacitor, a Metal-Oxide-Metal (MOM) capacitor, or a Metal-Oxide-Semiconductor (MOS) capacitor, without being limited thereto. When the capacitor (CAP) stores charges of a predetermined level or higher, the unit cell (UC) may be in a state of storing data “1”. When the capacitor (CAP) stores charges of a predetermined level or less, the unit cell (UC) may be in a state of storing data “0”.

In an operation of writing data “1” to the unit cell (UC), a bitline signal of a high level may be applied to the bitline (BL), and a wordline signal of a high level may be applied to the wordline (WL). When the transistor (TX) is turned on by the high-level wordline signal, the bitline (BL) may serve as a drain terminal of the transistor (TX), the capacitor (CAP) may serve as a source terminal of the transistor (TX), and a potential level of the capacitor (CAP) may increase (or be increased) by the high-level bitline signal, so that data “1” can be written to the unit cell (UC).

In an operation of writing data “0” to the unit cell (UC), a bitline signal of a low level may be applied to the bitline (BL), and a wordline signal of a high level may be applied to the wordline (WL). When the transistor (TX) is turned on, the bitline (BL) may serve as a source terminal of the transistor (TX), and the capacitor (CAP) may serve as drain terminal, and a potential level of the capacitor (CAP) may decrease (or be decreased) by the low-level bitline signal, so that data “0” can be written to the unit cell (UC).

In an operation of reading data of the unit cell (UC), the bitline signal may have a reference level located between the high level and the low level, and the wordline signal may

have a high level. When data “1” is written (stored) to the unit cell (UC) and the transistor (TX) is turned on, the potential level of the capacitor (CAP) is at a high level, so that the level of the bitline signal may become higher than the reference level. When data “0” is recorded in the unit cell (UC) and the transistor (TX) is turned on, the potential level of the capacitor (CAP) is at a low level, so that the level of the bitline signal may become lower than the reference level. The semiconductor device may determine whether the level of the bitline signal becomes higher than the reference level, and may read data of the unit cell (UC) based on the result of the determination.

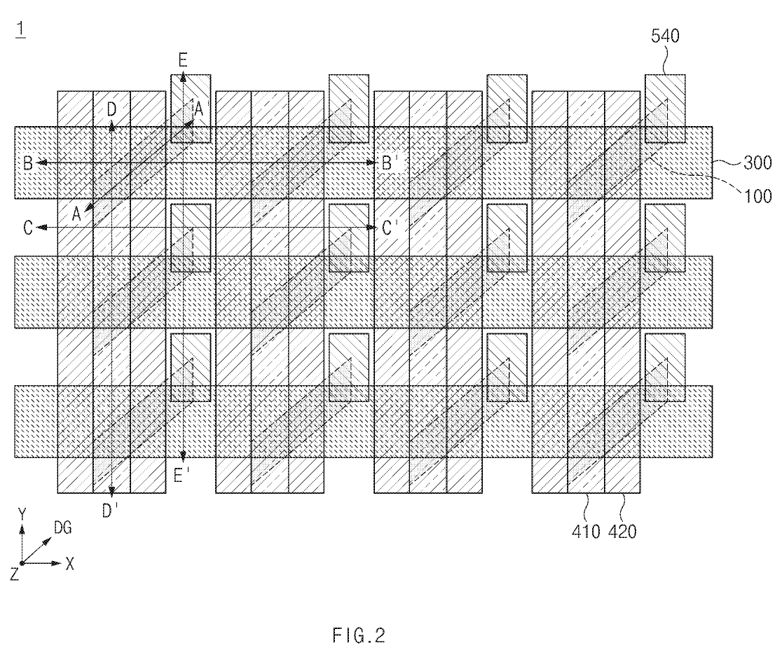

FIG. 2 is a first plan view illustrating an example of a portion of a semiconductor device 1 according to an embodiment of the present disclosure.

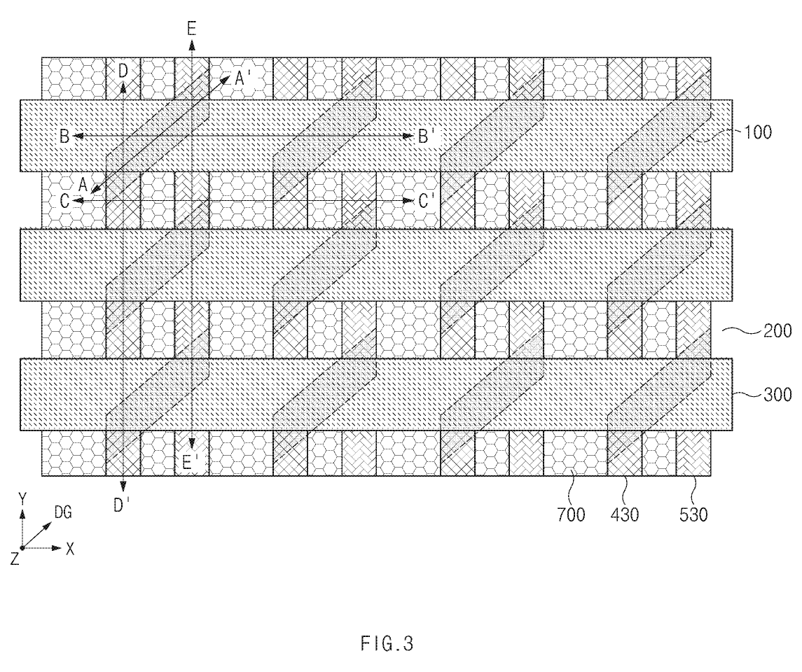

FIG. 3 is a second plan view illustrating an example of a portion of the semiconductor device 1 according to an embodiment of the present disclosure.

Referring to FIGS. 1, 2, and 3, the first plan view and the second plan view show, by way of example, the positional relationship between a plurality of active regions 100 and peripheral structures. The first plan view shows the positional relationship between the plurality of active regions 100, the plurality of wordline structures 300, and peripheral structures arranged on a surface of a predetermined semiconductor layer. The second plan view shows the positional relationship between the plurality of active regions 100 and peripheral structures arranged below the surface of the predetermined semiconductor layer.

The semiconductor device 1 may include the plurality of active regions 100, a cell isolation region 200, the plurality of wordline structures 300, a plurality of bitline electrode layers 410, a plurality of bitline spacers 420, a plurality of bitline pad regions 430, a plurality of storage-node pad regions 530, a plurality of storage-node contact regions 540, and a plurality of pad insulation layers 700.

Each of the plurality of active regions 100 may include a semiconductor material (e.g., silicon (Si), silicon carbide (SiC), etc.). Each of the plurality of active regions 100 may be surrounded by a cell isolation region 200. For example, the plurality of active regions 100 may be arranged in a matrix structure. The plurality of active regions 100 may be arranged in an (m × n) matrix structure (where ‘m’ is an integer greater than or equal to 2, and ‘n’ is an integer greater than or equal to 2). Each of the plurality of active regions 100 may extend in a diagonal direction (DG). The diagonal direction (DG) may be a diagonal direction with respect to a first direction (X). An angle between the diagonal direction (DG) and the first direction (X) may be an acute angle. Some of the plurality of active regions 100 may be repeatedly arranged to be spaced apart from each other in the first direction (X). Some of the plurality of active regions 100 may be repeatedly arranged to be spaced apart from each other in a second direction (Y) perpendicular to the first direction (X). Some of the plurality of active regions 100 may be repeatedly arranged to be spaced apart from each other in the diagonal direction (DG). An angle between the diagonal direction (DG) and the second direction (Y) may be an acute angle. An acute angle between the first direction (X) and the diagonal direction (DG) may be in a range of about 30 degrees to about 60 degrees. Each of the plurality of active regions 100 may overlap the wordline structure 300. Although each of the active regions 100 is illustrated, by way of example, as having a shape like a parallelogram, the scope of the present disclosure is not limited thereto. For example, each of the four corner regions of the active region 100 may have a round shape. Each of the plurality of active regions 100 may include a region in which a channel of a transistor (TX) of a unit cell (UC) is formed. Each of the plurality of active regions 100 may be surrounded by the cell isolation region 200. One end of each of the plurality of active regions 100 may overlap the bitline electrode layer 410. The other end of each of the plurality of active regions 100 may overlap

a storage-node contact region 540. One end of each of the plurality of active regions 100 may overlap a bitline pad region 430. The other end of each of the plurality of active regions 100 may overlap a storage-node pad region 530.

The cell isolation region 200 may include an insulative material. For example, the cell isolation region 200 may include at least one of silicon oxide or a Silicon-On-Insulator (SOI) structure. The cell isolation region 200 may surround each of the plurality of active regions 100. The cell isolation region 200 may provide electrical insulation between the plurality of active regions 100 spaced apart from each other.

Each of the plurality of wordline structures 300 may extend in the first direction (X). The plurality of wordline structures 300 may be arranged to be spaced apart from each other in the second direction (Y). Each of the plurality of wordline structures 300 may include a predetermined electrode layer to which a wordline signal is applied. When the wordline signal has a high level in an electrode layer included in the wordline structure 300, a predetermined channel may be formed within the active region 100 overlapping the wordline structure 300. Each of the plurality of wordline structures 300 may overlap each of the plurality of active regions 100 spaced apart from each other in the first direction (X). Although each of the plurality of wordline structures 300 may be formed to pass through the center of each of the plurality of active regions 100 spaced apart from each other in the first direction (X), other implementations may be provided in accordance with the present disclosure. As the center of each wordline structure 300 extends closer to the center of the active region 100 in the first direction (X), the overlap areas between the active region 100 and each of the bitline pad region 430 and the storage-node pad region 530 can be stably secured, thereby improving the reliability of the semiconductor device 1.

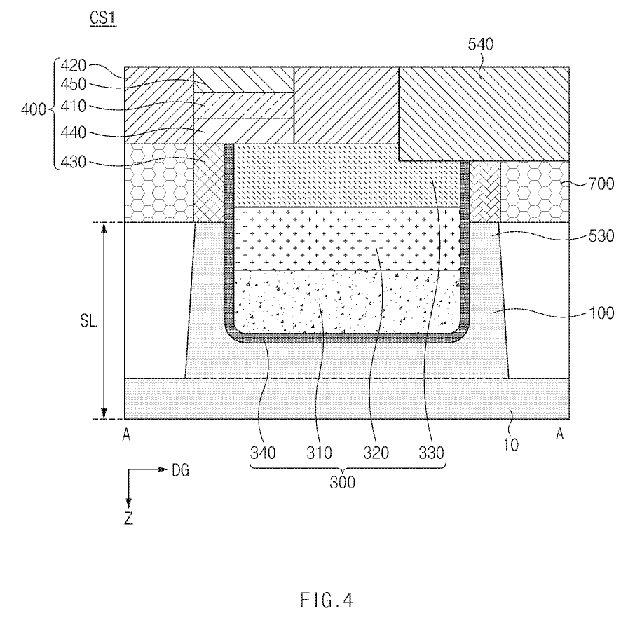

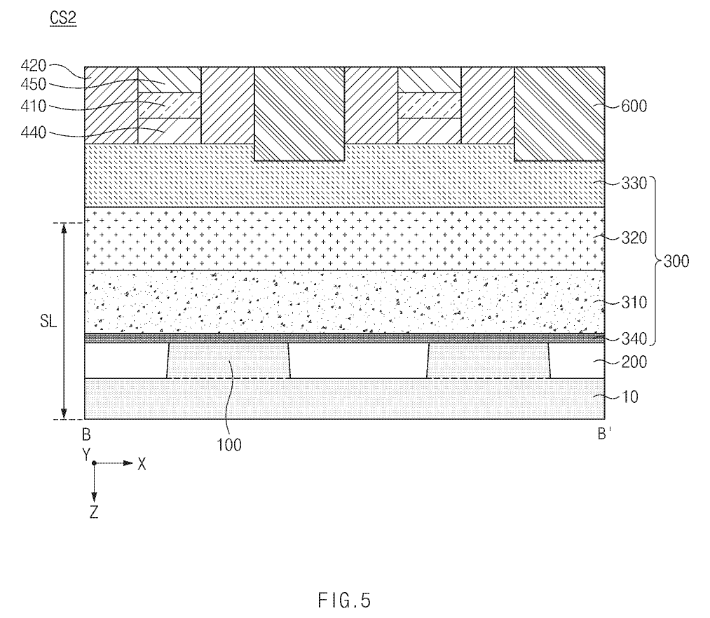

The internal structure of the wordline structures 300 will be described with reference to FIG. 4 and below.

Each of the plurality of bitline electrode layers 410 may include a conductive material. For example, each of the plurality of bitline electrode layers 410 may include a metal material such as aluminum (Al), copper (Cu), or tungsten (W). Each of the plurality of bitline electrode layers 410 may extend in the second direction (Y). The plurality of bitline electrode layers 410 may be arranged to be spaced apart from each other in the first direction (X). The first direction (X) and the second direction (Y) may be perpendicular to each other. Each of the plurality of bitline electrode layers 410 may be an electrode layer to which the bitline signal is applied. Each of the plurality of bitline electrode layers 410 may overlap the plurality of bitline pad regions 430 spaced apart from each other in the second direction (Y). Each of the plurality of bitline electrode layers 410 may intersect (cross) the plurality of wordline structures 300. Both side surfaces of each of the plurality of bitline electrode layers 410 may contact the bitline spacer 420. Each of the plurality of bitline electrode layers 410 may overlap one end of each active region 100.

Each of the plurality of bitline spacers 420 may include an insulative material. For example, each of the plurality of bitline spacers 420 may include an insulative material such as silicon oxide or silicon nitride. Each of the plurality of bitline spacers 420 may extend in the second direction (Y). The plurality of bitline spacers 420 may be arranged to be spaced apart from each other in the first direction (X). The plurality of bitline spacers 420 may prevent electrical interaction between the bitline electrode layers 410 spaced apart from each other. The plurality of bitline spacers 420 may form one pair, and one pair of the bitline spacers 420 may contact both side surfaces of the bitline electrode layer 410.

Each of the plurality of bitline pad regions 430 may include a conductive material. For example, each of the plurality of bitline pad regions 430 may include polysilicon. For example, the polysilicon may include predetermined impurities for improving conductivity. In another embodiment, each of the plurality of bitline pad regions 430 may include silicide. Each of the plurality of bitline pad regions 430 may be configured to transfer a bitline signal applied to a bitline electrode layer 410 to an active region 100. When the plurality of bitline pad regions 430 includes polysilicon doped with predetermined impurities or silicide, carrier concentration may increase, thereby improving electrical conductivity and reducing junction resistance, resulting in improvement in the operation characteristics of the semiconductor device 1. Each of the plurality of bitline pad regions 430 may be disposed between two adjacent wordline structures 300. For example, each of the plurality of bitline pad regions 430 may contact both side surfaces of two adjacent wordline structures 300 facing each other. The bitline pad region 430 may overlap one end of the active region 100. In an arbitrary active region 100, the bitline pad region 430 may contact one side of the wordline structure 300 overlapping the active region 100. The bitline pad region 430 may also contact a wordline structure 300 overlapping the active region 100 that is spaced apart from the active region 100 in a direction opposite to the second direction (Y). Some of the plurality of bitline pad regions 430 may be arranged to be spaced apart from each other in the first direction (X). Some others of the plurality of bitline pad regions 430 may be arranged to be spaced apart from each other in the second direction (Y).

Each of the plurality of storage-node pad regions 530 may include a different material from the bitline pad region 430. For example, each of the plurality of storage-node pad regions 530 may include a silicon material. Each of the plurality of storage-node pad regions 530 may include, for example, a monocrystalline silicon material formed by an epitaxial growth process from the active region 100. Each of the plurality of storage-node pad regions 530 may include a silicon material that does not contain impurities.

As the number of charge traps in the storage-node pad region 530 increases, charges stored in the capacitor (CAP) may leak into the charge traps of the storage-node pad region 530 and may not be stored again in the capacitor (CAP), thereby causing a possibility of data loss. Accordingly, when the storage-node pad region 530 includes a material with a low density of charge traps, such as impurity-free monocrystalline silicon, charge leakage from the capacitor (CAP) may be reduced, thereby enhancing data reliability and enabling data retention for a longer period of time.

Each of the plurality of storage-node pad regions 530 may be disposed between two adjacent wordline structures 300. For example, each of the plurality of storage-node pad regions 530 may contact two facing side surfaces of two adjacent wordline structures 300. The storage-node pad region 530 may overlap the other end of the active region 100, which is opposite to one end of the active region 100. In any given active region 100, the storage-node pad region 530 may contact one side of the wordline structure 300 overlapping the active region 100. The storage-node pad region 530 may also contact the wordline structure 300 overlapping the active region 100 that is spaced apart from the active region 100 in the second direction (Y). Some of the plurality of storage-node pad regions 530 may be arranged to be spaced apart from each other in the first direction (X). Some others of the plurality of storage-node pad regions 530 may be arranged to be spaced apart from each other in the second direction (Y).

Each of the plurality of storage-node contact regions 540 may include a conductive material. For example, each of the plurality of storage-node contact regions 540 may include at least one of polysilicon, aluminum, copper, or titanium. The polysilicon may include predetermined impurities to improve conductivity. Each of the storage-node contact regions 540 may be arranged between two adjacent bitlines. The storage-node contact regions 540 may overlap the other end of the active region 100. Some of the storage-node contact regions 540 may overlap the wordline structure 300 that overlaps the active region 100. The plurality of storage-node contact regions 540 may be arranged to be spaced apart from each other in the first direction (X). The plurality of storage-node contact regions 540 may be arranged to be spaced apart from each other in the second direction (Y).

Each of the plurality of pad insulation regions 700 may electrically isolate adjacent bitline pad regions 430 from the storage-node pad region 530. Each of the plurality of pad insulation regions 700 may be disposed between the bitline pad region 430 and the storage-node pad region 530 that are adjacent to each other. For example, each of the plurality of pad insulation regions 700 may be disposed between the bitline pad region 430 and the storage-node pad region 530 spaced apart from each other in the first direction (X). The plurality of pad insulation regions 700 may be repeatedly spaced apart from each other in the first direction (X) and the second direction (Y). Each of the plurality of pad insulation regions 700 may include an insulative material. For example, each of the plurality of pad insulation regions 700 may include an insulative material such as silicon oxide or silicon nitride.

FIG. 4 is a cross-sectional view illustrating an example structure of the semiconductor device 1 taken along the line A-A’ of FIGS. 2 and 3 according to an embodiment of the present disclosure.

Referring to FIGS. 2, 3, and 4, a first cross-section (CS1) may include a substrate region 10, an active region 100, a cell isolation region 200, a wordline structure 300, a bitline structure 400, a storage-node pad region 530, storage-node contact regions 540, and pad insulation regions 700.

The substrate region 10 may be a semiconductor region disposed below the active region 100. The substrate region 10 may include a semiconductor material. For example, the substrate region 10 may include at least one of silicon, silicon germanium, or a combination thereof.

The active region 100 may be disposed over the substrate region 10 and may extend up to a surface (i.e., a top surface in the drawings) of the semiconductor layer (SL). The active region 100 may contact the side surface and the bottom surface of the wordline structure 300. For example, the active region 100 may surround the side surface and the bottom surface of the wordline insulation layer 340. When a channel is formed in the active region 100, charge carriers may move from the bitline electrode layer 410 to the bitline contact region 440, the bitline pad region 430, the active region 100, the storage-node pad region 530, and the storage-node contact region 540, and may finally move to the capacitor (not shown) (CAP in FIG. 1) connected above the storage-node contact region 540. Additionally, such charge carriers may also move from the capacitor to the bitline electrode layer 410 in a direction opposite to the above movement. Both side surfaces of the active region 100 may contact the cell isolation region 200. The channel may be formed in the vicinity of the wordline insulation layer 340 when an operating voltage is applied to the wordline (see WL of FIG. 1).

The cell isolation region 200 may contact the side surface of the active region 100. The top surface of the cell isolation region 200 may contact the pad insulation region 700. The cell isolation region 200 may be formed recessed by a predetermined distance from the surface of the semiconductor layer (SL). The predetermined distance by which the cell isolation region 200 is recessed from the surface of the semiconductor layer (SL) may be, for example, between about 1600 Å and about 1900 Å, but the embodiments of the present disclosure are not limited thereto. In an example embodiment in which the bitline pad region 430 or the storage-node pad region 530 is formed thicker in a horizontal direction (for example, in direction X or direction DG) than that illustrated in FIGS. 3 and 4, the top surface of the cell isolation region 200 may also contact the bitline pad region 430 or the storage-node pad region 530.

The wordline structure 300 may include a first wordline electrode layer 310, a second wordline electrode layer 320, a wordline capping layer 330, and a wordline insulation layer 340. The wordline structure 300 may extend (or be recessed) from the same plane as the top surface of the bitline pad region 430 toward the inside of the semiconductor layer (SL) to a predetermined depth in the third direction (Z). The directions X, Y, and Z may be orthogonal to each other, for example, forming a Cartesian coordinate system. The wordline structure 300 is preferably formed in the central region of the active region 100, but may vary depending on fabrication limitations, variables, and defects. Here, the predetermined depth may be, for example, between about 1000 Å and about 1300 Å, but the embodiments of the present disclosure are not limited thereto. In the present disclosure, the surface of the semiconductor layer (SL) may be defined as a position of the same plane as the top surface of the active region 100 or the top surface of the cell isolation region 200.

The first wordline electrode layer 310 may include a conductive material. For example, the first wordline electrode layer 310 may include tungsten, aluminum, copper, tungsten nitride, tungsten silicide, cobalt silicide, titanium silicide, tantalum nitride, or a combination thereof. The first wordline electrode layer 310 may be disposed below the second wordline electrode layer 320. The side and bottom surfaces of the first wordline electrode layer 310 may be surrounded by a wordline insulation layer 340.

The second wordline electrode layer 320 may include a conductive material. For example, the second wordline electrode layer 320 may include tungsten, aluminum, copper, tungsten nitride, tungsten silicide, cobalt silicide, titanium silicide, tantalum nitride, or a combination thereof. The second wordline electrode layer 320 may be a region into which predetermined impurities (e.g., phosphorus, germanium, etc.) are implanted. The second wordline electrode layer 320 may be disposed over the first wordline electrode layer 310. The second wordline electrode layer 320 may be disposed below the wordline capping layer 330. Both side surfaces of the second wordline electrode layer 320 may contact the wordline insulation layer 340.

Although not shown in the drawings, a predetermined anti-oxidation layer may be arranged between the first wordline electrode layer 310 and the second wordline electrode layer 320. The predetermined anti-oxidation layer may capture (or collect) impurities (e.g., oxygen) contained in the first and second wordline electrode layers (310, 320).

Each of the first and second wordline electrode layers (310, 320) may receive a wordline signal as an input. When the wordline signal has a high level, a channel in which charges move may be formed around the wordline structure 300 within the active region 100. When the wordline signal has a low level, the channel may not be formed. When the channel is formed, the bitline electrode layer 410 and the storage-node contact region 540 may be electrically connected to each other. For example, in an operation of recording data “1”, when a high-level bitline signal is applied to the bitline electrode layer 410 and a wordline signal is applied to the first and second wordline electrode layers (310, 320), charges may move to the storage-node contact region 540 according to (based on) the bitline signal of the bitline electrode layer 410 through the bitline contact region 440, the bitline pad region 430, the channel, and the storage-node pad region 530. Since the storage-node contact region 540 may be electrically connected to a predetermined capacitor structure (not shown), the charges may be stored in the capacitor structure through the storage-node contact region 540. The capacitor structure may be modeled in a circuit diagram as in the capacitor (CAP) of FIG. 1.

The wordline capping layer 330 may include an insulative material. For example, the wordline capping layer 330 may include silicon nitride, silicon oxide, silicon oxynitride, or a combination thereof. The wordline capping layer 330 may be disposed over the second wordline electrode layer 320. The wordline capping layer 330 may be a region filled with an insulative material between a surface of the semiconductor layer (SL) and a top surface of the second wordline electrode layer 320. The wordline capping layer 330 may electrically isolate the first and second wordline electrode layers (310, 320) from the bitline structure 400. The wordline capping layer 330 may electrically isolate the first and second wordline electrode layers (310, 320) from the storage-node contact region 540. Although the depth of the wordline capping layer 330 from the surface of the semiconductor layer (SL) is depicted as shallower than the depth of the bitline pad region 430 or the depth of the storage-node pad region 530 as shown in the drawings for convenience of description, other implementations may be provided in accordance with the present disclosure. According to another embodiment, the depth of the wordline capping layer 330 may also be formed deeper than the depth of the bitline pad region 430 and the depth of the storage-node pad region 530.

The wordline insulation layer 340 may include an insulative material. For example, the wordline insulation layer 340 may include silicon oxide, hafnium oxide, hafnium silicon oxide, hafnium silicon oxynitride, or a combination thereof. The wordline insulation layer 340 may be formed along the side and bottom surfaces of the wordline structure 300. The wordline insulation layer 340 may physically isolate the first and second wordline electrode layers (310, 320) from the active region 100. The wordline insulation layer 340 may electrically isolate the first and second wordline electrode layers (310, 320) from the storage-node pad region 530. The wordline insulation layer 340 may also electrically isolate the first and second wordline electrode layers (310, 320) from the storage-node pad region 530.

The bitline structure 400 may include a bitline electrode layer 410, a bitline spacer 420, a bitline pad region 430, a bitline contact region 440, and a bitline capping layer 450.

The bitline electrode layer 410 may include a conductive material. For example, the bitline electrode layer 410 may include tungsten, aluminum, copper, tungsten nitride, tungsten silicide, cobalt silicide, titanium silicide, tantalum nitride, or a combination thereof. The bitline electrode layer 410 may be disposed spaced apart from the surface of the semiconductor layer (SL). The bitline electrode layer 410 may be disposed spaced apart from the bitline pad region 430. When viewed in the third direction (Z), the bitline electrode layer 410 may overlap the bitline pad region 430. The bitline electrode layer 410 may also overlap the wordline structure 300. Each of the side surfaces of the bitline electrode layer 410 may contact the bitline spacer 420. The bitline electrode layer 410 may be disposed below the bitline capping layer 450.

The bitline spacer 420 may include an insulative material. For example, the bitline spacer 420 may include at least one of silicon oxide, silicon nitride, silicon oxynitride, or a combination thereof. The bitline spacer 420 may contact both side surfaces of the bitline electrode layer 410. The bitline spacer 420 may contact both side surfaces of the bitline contact region 440. The bitline spacer 420 may also contact both side surfaces of the bitline capping layer 450. The bitline spacer 420 may electrically isolate the bitline electrode layer 410 from the storage-node contact region 540. The bitline spacer 420 may also electrically isolate the bitline contact region 440 from the storage-node contact region 540.

The bitline pad region 430 may include a conductive material. For example, the bitline pad region 430 may include polysilicon. The polysilicon may contain predetermined impurities. The bitline pad region 430 may include silicide. The bitline pad region 430 may be disposed over the semiconductor layer (SL). The bitline pad region 430 may be disposed over the same plane as the surface of the semiconductor layer (SL). The top surface of the bitline pad region 430 may be disposed over the same plane as the top surface of the pad insulation region 700 or the wordline structure 300. The bottom surface of the bitline pad region 430 may contact the active region 100. One side of the bitline pad region 430 may contact the wordline structure 300. The other side of the bitline pad region 430 may contact the pad insulation region 700. The top surface of the bitline pad region 430 may contact the bitline contact region 440.

In a situation where there is no bitline pad region 430, when the wordline structure 300 is misaligned from the center of the active region 100 toward the bitline contact region 440 (based on FIG. 4, when the wordline structure 300 is formed to be shifted (or biased) to the left), a contact area between the bitline contact region 440 and the active region 100 may decrease in size, and there may occur various problems such as increased contact resistance, decreased current capacity, and performance degradation caused by increased temperature. However, when the bitline pad region 430 is formed, the top surface of the bitline pad region 430 may secure a contact area with the bitline contact region 440, and the bottom surface of the bitline pad region 430 may secure a contact area with the active region 100, so that the contact resistance is reduced, the current capacity is increased, and the temperature increase is lowered, thereby improving performance of the semiconductor device 1.

The bitline contact region 440 may include a conductive material. For example, the bitline contact region 440 may include at least one of polysilicon, copper, aluminum, titanium, titanium nitride, or a combination thereof. The bitline contact region 440 may be formed of the same material as the bitline electrode layer 410, or may be formed of a different material from the bitline electrode layer 410. When the bitline contact region 440 is formed of a different material from the bitline electrode layer 410, for example, it may be advantageous for the bitline electrode layer 410 to be formed of a metal material having high conductivity, whereas it may be advantageous for the bitline contact region 440 to be formed of a material favorable for reducing contact resistance between the bitline electrode layer 410 and the bitline pad region 430. The bitline contact region 440 may contact (or be in contact with) the bottom surface of the bitline electrode layer 410. Each of the side surfaces of the bitline contact region 440 may contact the bitline spacer 420. The bottom surface of the bitline contact region 440 may contact the bitline pad region 430. The bitline contact region 440 may be disposed over the semiconductor layer (SL).

The bitline capping layer 450 may include an insulative material. For example, the bitline capping layer 450 may include silicon oxide, silicon nitride, silicon oxynitride, or a combination thereof. The bitline capping layer 450 may contact the top surface of the bitline electrode layer 410. The bitline capping layer 450 may contact the bitline spacer 420. The bitline capping layer 450 together with the bitline spacer 420 may prevent both the bitline electrode layer 410 and the bitline contact region 420 from electrically interacting with components disposed around the bitline structure 400.

The storage-node pad region 530 may include silicon. For example, the storage-node pad region 530 may include monocrystalline silicon that does not contain impurities. The storage-node pad region 530 may be disposed over the semiconductor layer (SL). A bottom surface of the storage-node pad region 530 may be disposed over the same plane as the surface of the semiconductor layer (SL). A top surface of the storage-node pad region 530 may be disposed at a position equal to or lower than the top surface of the bitline pad region 430. The bottom surface of the storage-node pad region 530 may contact the active region 100. One side of the storage-node pad region 530 may contact a pad insulation region 700. The other side of the storage-node pad region 530 may contact the wordline structure 300. The top surface of the storage-node pad region 530 may contact the storage-node contact region 540.

In a situation where there is no storage-node pad region 530, when the wordline structure 300 is misaligned from the center of the active region 100 toward the storage-node contact region 540 (based on FIG. 4, when the wordline structure 300 is formed to be shifted (or biased) to the right), the contact area between the storage-node contact region 540 and the active region 100 may decrease in size, and there may occur various problems such as increased contact resistance, decreased current capacity, and performance degradation caused by increased temperature. However, when the storage-node pad region 530 is formed, the top surface of the storage-node pad region 530 may secure a contact area with the storage-node contact region 540, and the bottom surface of the storage-node pad region 530 may secure a contact area with the active region 100, so that the contact resistance is reduced, the current capacity is increased, and the temperature increase is lowered, thereby improving performance of the semiconductor device 1.

Unlike the bitline pad region 430, the storage-node pad region 530 may include a material that is not doped with impurities and has a relatively low density of charge traps, thereby preventing leakage of charges stored in the capacitor (CAP of FIG. 1) and enabling data to be retained for a relatively longer period of time.

The storage-node contact region 540 may include a conductive material. For example, the storage-node contact region 540 may include at least one of polysilicon, copper, aluminum, titanium, titanium nitride, or a combination thereof. A bottom surface of the storage-node contact region 540 may contact the storage-node pad region 530. One side surface of the storage-node contact region 540 may contact the bitline spacer 420.

The pad insulation region 700 may include an insulative material. For example, the pad insulation region 700 may include silicon oxide or silicon nitride. The pad insulation region 700 may be disposed over the semiconductor layer (SL). A bottom surface of the pad insulation region 700 may be disposed over the same plane as the surface of the semiconductor layer (SL). A top surface of the pad insulation region 700 may be disposed over the same plane as the top surface of either the bitline pad region 430 or the wordline structure 300. The bottom surface of the pad insulation region 700 may contact a cell isolation region 200 (or structure). One side surface of the pad insulation region 700 may contact the bitline pad region 430. The other side surface of the pad insulation region 700 may contact the storage-node pad region 530. The top surface of the pad insulation region 700 may contact the bitline spacer 420 or the storage-node contact region 540.

In the following description of FIGS. 5 to 18F, descriptions overlapping with FIGS. 1 to 4 will herein be may omitted for conciseness and clarity.

FIG. 5 is a cross-sectional view illustrating an example structure of the semiconductor device taken along the line B-B’ of FIGS. 2 and 3 according to an embodiment of the present disclosure.

Referring to FIGS. 2, 3, 4, and 5, the second cross-section (CS2) may include a substrate region 10, an active region 100, a cell isolation region 200, a first wordline electrode layer 310, a second wordline electrode layer 320, a wordline capping layer 330, a wordline insulation layer 340, a bitline electrode layer 410, a bitline spacer 420, a bitline contact region 440, a bitline capping layer 450, and a contact insulation region 600.

The first wordline electrode layer 310 may extend in the first direction (X). The first wordline electrode layer 310 may be disposed over the wordline insulation layer 340. The second wordline electrode layer 320 may extend in the first direction (X). The second wordline electrode layer 320 may be disposed over the first wordline electrode layer 310. The wordline capping layer 330 may extend in the first direction (X). The wordline capping layer 330 may be disposed over the second wordline electrode layer 320. The wordline insulation layer 340 may extend in the first direction (X). The bottom surface of the wordline insulation layer 340 may contact each of the cell isolation region 200 and the active region 100.

In FIG. 5, the bottom surface of the wordline insulation layer 340 is illustrated as being formed horizontally, but other implementations are also possible. Alternatively, depending on the process methods, the etching speed of the active region 100 and the etching speed of the cell isolation region 200 may be different from each other, and the bottom surface of the wordline insulation layer 340 may be located at a lower position over the cell isolation region 200 than over the active region 100 (i.e., the wordline insulation layer 340 may be located at a deeper position over the cell isolation region 200 than over the active region 100). Hereinafter, the present disclosure will describe, by way of example, an embodiment in which the bottom surface of the wordline insulation layer 340 is formed horizontally.

A plurality of bitline electrode layers 410 may be arranged to be spaced apart from each other in the first direction (X). Both side surfaces of each of the plurality of bitline electrode layers 410 may contact the bitline spacers 420. The contact insulation region 600 may be disposed between the bitline spacers 420 arranged on surfaces on one side of the different bitline electrode layers 410.

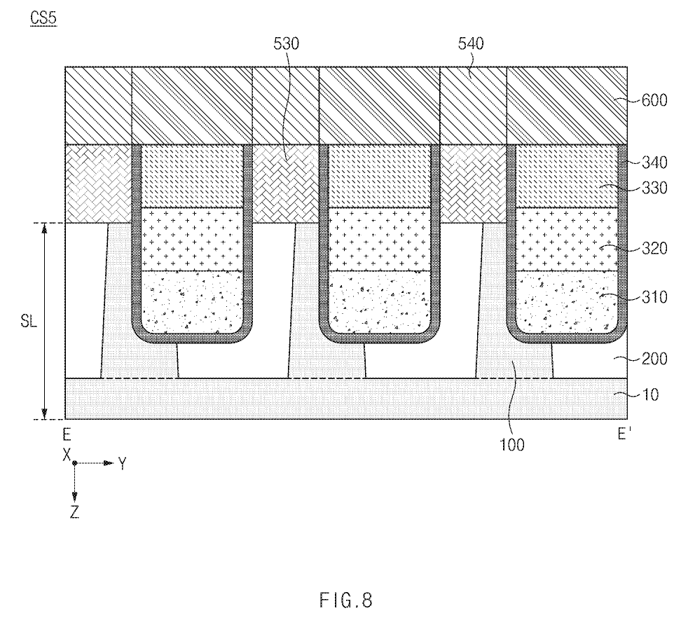

The contact insulation regions 600 may include an insulative material. For example, the contact insulation region 600 may include at least one of silicon oxide, silicon nitride, silicon oxynitride, or a combination thereof. The contact insulation region 600 may be disposed between adjacent bitline spacers 420. The contact insulation region 600 may be repeatedly spaced apart from each other in the first direction (X). The contact insulation region 600 will be described in more detail herein below with reference to FIG. 8.

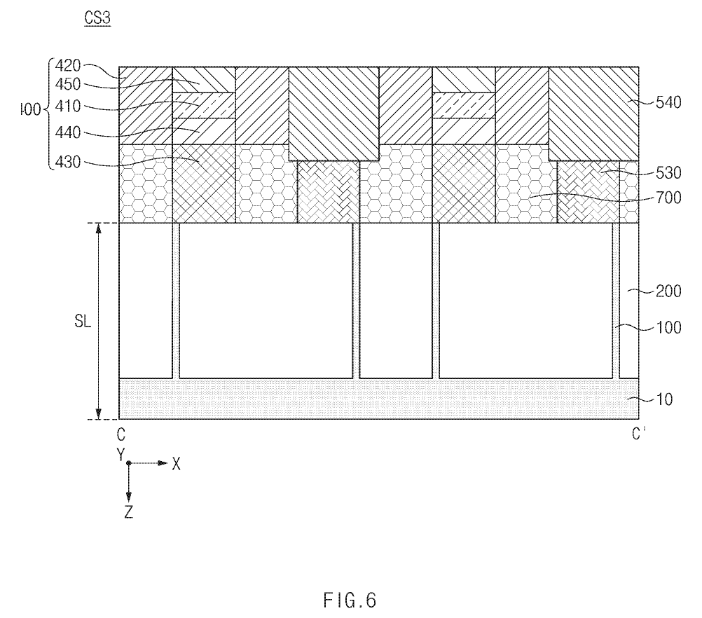

FIG. 6 is a cross-sectional view illustrating an example structure of the semiconductor device taken along the line C-C’ of FIGS. 2 and 3 according to an embodiment of the present disclosure.

Referring to FIGS. 2, 3, 4, and 6, the third cross-section (CS3) may include a substrate region 10, an active region 100, a cell isolation region 200, a bitline electrode layer 410, a bitline spacer 420, a bitline pad region 430, a bitline contact region 440, a bitline capping layer 450, a storage-node pad region 530, a storage-node contact region 540, and a pad insulation region 700.

A bottom surface of the bitline pad region 430 may contact the active region 100 and the cell isolation region 200. Each of both side surfaces of the bitline pad region 430 may contact the pad insulation region 700. A top surface of the bitline pad region 430 may contact the bitline contact region 440.

The storage-node pad region 530 may contact the top surface of the active region 100. Each of both side surfaces of the storage-node pad region 530 may contact the pad insulation region 700. The top surface of the storage-node pad region 530 may contact the storage-node contact region 540.

Each of the plurality of bitline pad regions 430 and each of the storage-node pad regions 530 may be alternately arranged in the first direction (X). The height of the bitline pad region 430 may differ from the height of the storage-node pad region 530, but the scope of the present disclosure is not limited thereto. For example, the height of the bitline pad region 430 may be the same as the height of the storage-node pad region 530. In a process of forming the storage-node contact region 540, when the storage-node contact region 540 is completely brought into contact with the storage-node pad region 530 without etching a portion of the storage-node pad region 530, the height of the storage-node pad region 530 may be the same as the height of the bitline pad region 430.

Each of the plurality of bitline pad regions 430, each of the plurality of storage-node pad regions 530, and each of the plurality of pad insulation regions 700 may be disposed over the same plane as the surface of the active regions 100.

Each of the plurality of bitline contact regions 440 may contact the top surface of the bitline pad region 430. On the other hand, each of the plurality of storage-node contact regions 540 may contact the top surface of the storage-node pad region 530.

The pad insulation region 700 may be disposed between the storage-node pad region 530 and the adjacent bitline pad regions 430. The bottom surface of the pad insulation region 700 may contact the cell isolation region 200. For example, the top surface of the pad insulation region 700 may be disposed over the same plane as the top surface of the bitline pad region 430.

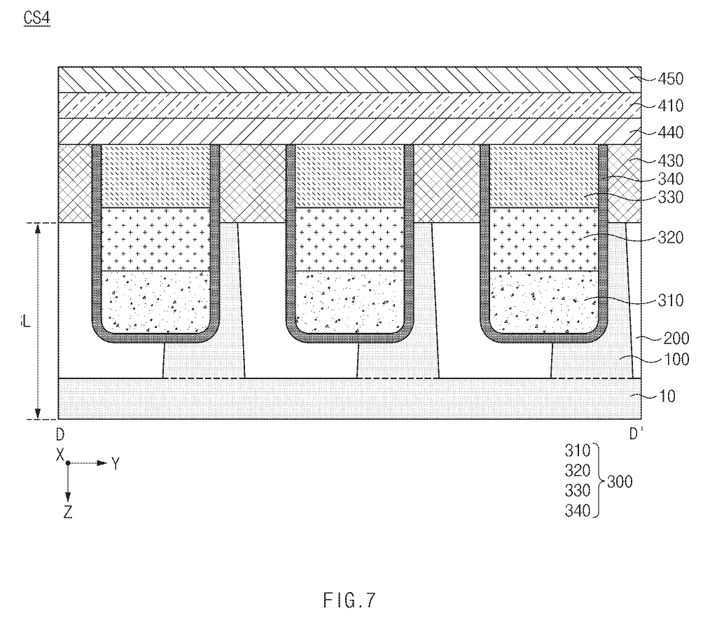

FIG. 7 is a cross-sectional view illustrating an example structure of the semiconductor device 1 taken along the line D-D’ of FIGS. 2 and 3 according to an embodiment of the present disclosure.

Referring to FIGS. 2, 3, 4, and 7, the fourth cross-section (CS4) may include a substrate region 10, an active region 100, a cell isolation region 200, a bitline pad region 430, a first wordline electrode layer 310, a second wordline electrode layer 320, a wordline capping layer 330, a wordline insulation layer 340, a bitline electrode layer 410, a bitline contact region 440, and a bitline capping layer 450.

The bitline electrode layer 410 may extend in the second direction (Y). The bitline contact region 440 may extend in the second direction (Y). The bitline capping layer 450 may extend in the second direction (Y).

A portion (e.g., a lower portion) of the bottom surface of the wordline structure 300 may contact the active region 100. Another portion of the bottom surface of the wordline structure 300 may contact the cell isolation region 200. A portion (e.g., a lower portion) of one side of the wordline structure 300 may contact the active region 100. Another portion (e.g., an upper portion) of one side of the wordline structure 300 may contact the bitline pad region 430. A portion (e.g., a lower portion) of the other side of the wordline structure 300 may contact the cell isolation region 200. Another portion (e.g., an upper portion) of the other side of the wordline structure 300 may contact the bitline pad region 430.

Each of the plurality of bitline pad regions 430 may be disposed between adjacent wordline structures 300.

FIG. 8 is a cross-sectional view illustrating an example structure of the semiconductor device 1 taken along the line E-E’ of FIGS. 2 and 3 according to an embodiment of the present disclosure.

Referring to FIGS. 2, 3, 4, and 8, the fifth cross-section (CS5) may include a substrate region 10, an active region 100, a cell isolation region 200, a wordline structure 300, a storage-node pad region 530, a storage-node contact region 540, and a contact insulation region 600.

Both side surfaces of each of the plurality of storage-node contact regions 540 may contact the contact insulation regions 600. Both side surfaces of each of the plurality of contact insulation regions 600 may contact the storage-node contact region 540. The plurality of storage-node contact regions 540 and the plurality of contact insulation regions 600 may be alternately and repeatedly arranged in the second direction (Y).

The active region 100 may contact a portion of the bottom surface of the wordline structure 300 and a portion (e.g., a lower portion) of one side surface (e.g., the left side in FIG. 8) of the wordline structure 300. The cell isolation region 200 may contact another portion of the bottom surface of the wordline structure 300 and a portion (e.g., a lower portion) of another side surface (e.g., the right side in FIG. 8) of the wordline structure 300.

The storage-node pad region 530 may contact a portion (e.g., an upper portion) of one side of the wordline structure 300. The storage-node pad region 530 may contact a portion (e.g., an upper portion) of the other side of the wordline structure 300.

The contact insulation region 600 may be disposed over the wordline structure 300. For example, the contact insulation region 600 may contact a top surface of the wordline capping layer 330.

FIG. 9 is a flowchart illustrating an example of a method for manufacturing the semiconductor device 1 according to an embodiment of the present disclosure.

Referring to FIGS. 2, 3, and 9, a method for manufacturing the semiconductor device 1 (hereinafter referred to as “the present manufacturing method”) may include forming (S10) a plurality of active regions 100 and a cell isolation region 200 surrounding the plurality of active regions 100.

The method for manufacturing the semiconductor device 1 may include depositing an active layer over the plurality of active regions 100 and the cell isolation regions 200 (S20). The active layer may include the same material as the bitline pad region 430 or the storage-node pad region 530. In an example where the active layer includes the same material as the bitline pad region 430, the manufacturing method may include forming the bitline pad region 430 first and subsequently forming the storage-node pad region 530. In another example where the active layer includes the same material as the storage-node pad region 530, the manufacturing method may include forming the storage-node pad region 530 first and subsequently forming the bitline pad region 430.

The manufacturing method may include forming a plurality of first pad regions by removing a portion of the active layer (S30). In an example of the manufacturing method in which the active layer includes the same material as the bitline pad region 430, the first pad regions may correspond to the bitline pad regions 430. In another example of the manufacturing method in which the active layer includes the same material as the storage-node pad region 530, the first pad regions may correspond to the storage-node pad regions 530.

The operation (S20) of depositing the active layer and the operation (S30) of removing a portion of the active layer may be regarded as being included in the operation of forming the plurality of first pad regions.

The manufacturing method may include forming filling regions between the plurality of first pad regions (S40). The filling regions may be regions including the same material as the pad insulation regions 700.

The manufacturing method may include forming a plurality of pad insulation regions 700 by removing a portion of (i.e., partially removing) the filling regions (S50).

The operation (S40) of forming the filling regions and the operation (S50) of removing a portion of the filling regions may be regarded as being included in the operation of forming the plurality of pad insulation regions 700. However, the scope of the operation of forming the pad insulation regions 700 is not limited thereto. For example, as a representative method for forming sidewalls on both side surfaces of each of the first pad regions, a method for forming the pad insulation region 700 may also be included in the operation of forming the pad insulation region 700 according to the present disclosure.

The manufacturing method may include forming a plurality of second pad regions (S60). Each of the second pad regions may be located in a space from which the filling region has been removed. In an embodiment where the first pad regions correspond to the bitline pad regions 430, the second pad regions may represent the storage-node pad regions 530. In an embodiment where the first pad regions correspond to the storage-node pad regions 530, the second pad regions may represent the bitline pad regions 430.

The manufacturing method may include forming a plurality of wordline structures 300 (S70). The manufacturing method may further include forming a plurality of bitline electrode layers 410, a plurality of bitline spacers 420, a plurality of bitline contact regions 440, and a plurality of bitline capping layers 450 (S80). The manufacturing method may further include forming a plurality of storage-node contact regions 540 and a plurality of contact insulation regions 600 (S90).

The present manufacturing method will be described in more detail with reference to the plurality of cross-sectional views of FIG. 10A and below.

A representative example of the manufacturing method in which the first pad regions correspond to bitline pad regions 430 and the second pad regions correspond to storage-node pad regions 530 will hereinafter be described in more detail with reference to FIGS. 10A to 18F.

FIGS. 10A to 18F are plan views or cross-sectional views illustrating, by way of example, a method of manufacturing the semiconductor device 1 shown in FIG. 9.

FIG. 10A is a plan view illustrating an example result of performing operation S10 of FIG. 9.

Referring to FIGS. 2, 3, 9, and 10A to 10F, a method for manufacturing the semiconductor device 1 (hereinafter referred to as “the present manufacturing method”) may include forming (S10) a plurality of active regions 100 and a cell isolation region 200 surrounding the plurality of active regions 100.

Referring to FIG. 10A, some of the plurality of active regions 100 may be repeatedly arranged to be spaced apart from each other in the first direction (X). Some others of the plurality of active regions 100 may be repeatedly arranged to be spaced apart from each other in the second direction (Y) perpendicular to the first direction (X). Other parts of the plurality of active regions 100 may be repeatedly arranged to be spaced apart from each other in a diagonal direction (DG).

Each of the plurality of active regions 100 may extend in the diagonal direction (DG). An angle between the diagonal direction (DG) and the first direction (X) may be in a range of about 30 degrees to about 60 degrees.

Thereafter, a cell isolation region 200 may be formed to gap-fill the remaining empty spaces except for the plurality of active regions 100 with an insulative material (e.g., silicon oxide, silicon nitride, silicon oxynitride, etc.).

FIG. 10B is a cross-sectional view illustrating an example structure of the semiconductor device 1 taken along the line A-A’ of FIG. 10A according to an embodiment of the present disclosure.

Referring to FIGS. 10A and 10B, a predetermined trench may be formed from the top surface of the semiconductor layer (SL) including a semiconductor material (e.g., silicon, silicon germanium, etc.). The remaining region after formation of the trench may be the active region 100 or the substrate region 10. In some embodiments, the active region 100 may be defined as a region having the same depth as the predetermined trench. In the present disclosure, the substrate region 10 may contact the bottom surface of the active region 100, and may be defined as the remaining region except for the active region 100 after the predetermined trench is formed.

After the predetermined trench is formed, the cell isolation region 200 may be formed by gap-filling the trench with an insulative material.

FIG. 10C is a cross-sectional view illustrating an example structure of the semiconductor device taken along the line B-B’ of FIG. 10A according to an embodiment of the present disclosure.

FIG. 10D is a cross-sectional view illustrating an example structure of the semiconductor device taken along the line C-C’ of FIG. 10A according to an embodiment of the present disclosure.

Referring to FIGS. 10A, 10C, and 10D, the plurality of active regions 100 may be repeatedly formed in the first direction (X) by the operation of forming the predetermined trench. The cell isolation region 200 may be formed between the plurality of active regions 100.

FIG. 10E is a cross-sectional view illustrating an example structure of the semiconductor device 1 taken along the line D-D’ of FIG. 10A according to an embodiment of the present disclosure.

FIG. 10F is a cross-sectional view illustrating an example structure of the semiconductor device 1 taken along the line E-E’ of FIG. 10A according to an embodiment of the present disclosure.

Referring to FIGS. 10A, 10E, and 10F, the plurality of active regions 100 may be repeatedly formed in the second direction (Y) by the operation of forming the predetermined trench. The cell isolation region 200 may be formed between the plurality of active regions 100.

The following embodiments of FIGS. 11A to 11F will hereinafter be described with a focus on the characteristics that are different from those of FIGS. 10A to 10F.

FIG. 11A is a plan view illustrating an example result of performing operation S20 of FIG. 9 according to an embodiment of the present disclosure.

Referring to FIGS. 2, 3, 9, and 11A to 11F, the present manufacturing method may include forming an active layer (DAT) that overlaps each of the plurality of active regions 100 and each of the cell isolation regions 200 (S20).

The active layer (DAT) may include, for example, at least one of a silicide, polysilicon containing impurities, or a combination thereof. In another embodiment in which the storage-node pad region 530 is formed first, the active layer (DAT) may include undoped monocrystalline silicon.

Referring to FIGS. 10A and 11A, the active layer (DAT) overlapping each of the plurality of active regions 100 and each of the cell isolation regions 200 may be formed.

FIG. 11B is a cross-sectional view illustrating an example structure of the semiconductor device 1 taken along the line A-A’ of FIG. 11A according to an embodiment of the present disclosure.

Referring to FIGS. 10A, 11A, and 11B, the active layer (DAT) may be formed over the semiconductor layer (SL). The active layer (DAT) may be disposed over the semiconductor layer (SL) with a predetermined thickness.

FIG. 11C is a cross-sectional view illustrating an example structure of the semiconductor device 1 taken along the line B-B’ of FIG. 11A according to an embodiment of the present disclosure.

FIG. 11D is a cross-sectional view illustrating an example structure of the semiconductor device 1 taken along the line C-C’ of FIG. 11A according to an embodiment of the present disclosure.

Referring to FIGS. 10A, 11A, 11C, and 11D, the active layer (DAT) may be formed to extend in the first direction (X) on the surface of the semiconductor layer (SL).

FIG. 11E is a cross-sectional view illustrating an example structure of the semiconductor device 1 taken along the line D-D’ of FIG. 11A according to an embodiment of the present disclosure.

FIG. 11F is a cross-sectional view illustrating an example structure of the semiconductor device 1 taken along the line E-E’ of FIG. 11A according to an embodiment of the present disclosure.

Referring to FIGS. 10A, 11A, 11E, and 11F, the active layer (DAT) may be formed to extend in the second direction (Y) on the surface of the semiconductor layer (SL).

The following embodiments of FIGS. 12A to 12F will hereinafter be described with a focus on the characteristics that are different from those of FIGS. 11A to 11F.

FIG. 12A is a plan view illustrating an example result of performing operation S30 of FIG. 9 according to an embodiment of the present disclosure.

Referring to FIGS. 2, 3, 9, and 12A to 12F, the present manufacturing method may include removing a portion of the active layer (DAT) to form a plurality of bitline pad regions 430 (S30).

Referring to FIGS. 11A and 12A, at least one first removal region (DEL1) may refer to a region where the active layer (DAT) is to be removed. The first removal region (DEL1) may extend in the second direction (Y). The first removal region (DEL1) may be repeatedly arranged in the first direction (X).

The active layer (DAT) may overlap one end of the active region 100 and may be formed as a structure extending in the second direction (Y), so that the resultant active layer (DAT) may serve as the bitline pad region 430.

FIG. 12B is a cross-sectional view illustrating an example structure of the semiconductor device 1 taken along the line A-A’ of FIG. 12A according to an embodiment of the present disclosure.

FIG. 12C is a cross-sectional view illustrating an example structure of the semiconductor device taken along the line B-B’ of FIG. 12A according to an embodiment of the present disclosure.

FIG. 12D is a cross-sectional view illustrating an example structure of the semiconductor device taken along the line C-C’ of FIG. 12A according to an embodiment of the present disclosure.

Referring to FIGS. 11A and 12A to 12D, the bitline pad region 430 may be disposed over one end (e.g., a left end in FIG. 12B) of the active region 100. First removal regions (DEL1) may be disposed at both sides of the bitline pad region 430.

The first removal region (DEL1) may be located over the center of the active region 100 and over the other end (e.g., a right end in FIG. 12B) of the active region 100.

The bitline pad regions 430 may be spaced apart from each other repeatedly in the first direction (X). The spaces between the bitline pad regions 430 spaced apart from each other in the first direction (X) may correspond to the first removal regions (DEL1).

FIG. 12E is a cross-sectional view illustrating an example structure of the semiconductor device 1 taken along the line D-D’ of FIG. 12A according to an embodiment of the present disclosure.

FIG. 12F is a cross-sectional view illustrating an example structure of the semiconductor device 1 taken along the line E-E’ of FIG. 12A according to an embodiment of the present disclosure.

Referring to FIGS. 11A, 12A, 12E, and 12F, the bitline pad region 430 may extend in the second direction (Y). The first removal region (DEL1) may also extend in the second direction (Y).

The following embodiments of FIGS. 13A to 13F will hereinafter be described with a focus on the characteristics that are different from those of FIGS. 12A to 12F.

FIG. 13A is a plan view illustrating an example result of performing operation S40 of FIG. 9 according to an embodiment of the present disclosure.

Referring to FIGS. 2, 3, 9, and 13A to 13F, the present manufacturing method may include forming at least one filling region (FIL) between the plurality of bitline pad regions 430 (S40).

The filling region (FIL) may be a region that gap-fills the first removal region (DEL1). While the first removal region (DEL1) corresponds to an empty space, the filling region (FIL) may include the same material (e.g., an insulative material) as the pad insulation region (see 700 in FIG. 3).

The filling region (FIL) of FIGS. 13A to 13F may be formed at the position where the first removal region (DEL1) of FIGS. 12A to 12F is formed.

The following embodiments of FIGS. 14A to 14F will hereinafter be described with a focus on the characteristics that are different from those of FIGS. 13A to 13F.

FIG. 14A is a plan view illustrating an example result of performing operation S50 of FIG. 9 according to an embodiment of the present disclosure.

Referring to FIGS. 2, 3, 9, and 14A to 14F, the present manufacturing method may include forming a plurality of pad insulation regions 700 by removing a portion of the filling region (FIL) (S50).

Referring to FIGS. 13A and 14A, a second removal region (DEL2) may be formed by removing a portion of the filling region (FIL). The remaining portion of the filling region (FIL) after the formation of the second removal region (DEL2) may serve as the pad insulation region 700.

The second removal region (DEL2) may be formed at a position where the storage-node pad region 530 is to be formed. For example, the second removal region (DEL2) may overlap the other end (e.g., the right end in FIG. 14B) of each of the plurality of active regions 100 and may extend in the second direction (Y). The second removal regions (DEL2) may be repeatedly spaced apart from each other in the first direction (X).

The pad insulation region 700, which is the remaining portion of the filling region (FIL) after formation of the second removal region (DEL2), may be disposed between the

second removal region (DEL2) and the bitline pad region 430. The pad insulation region 700 may overlap the center of each of the plurality of active regions 100 and may extend in the second direction (Y).

FIG. 14B is a cross-sectional view illustrating an example structure of the semiconductor device 1 taken along the line A-A’ of FIG. 14A according to an embodiment of the present disclosure.

FIG. 14C is a cross-sectional view illustrating an example structure of the semiconductor device 1 taken along the line B-B’ of FIG. 14A according to an embodiment of the present disclosure.

FIG. 14D is a cross-sectional view illustrating an example structure of the semiconductor device 1 taken along the line C-C’ of FIG. 14A according to an embodiment of the present disclosure.

Referring to FIGS. 13A and 14A to 14D, when a second removal region (DEL2) is formed while the bitline pad region 430 is disposed over one end (e.g., the left end of FIG. 14B) of the active region 100, the second removal region (DEL2) may be formed over the other end (e.g., the right end in FIG. 14B) of the active region 100, and the pad insulation region 700 may be disposed over the center of the active region 100. The second removal region (DEL2) may be an empty space. Each side of the second removal region (DEL2) may contact the pad insulation region 700. The second removal region (DEL2) may be formed such that the filling region (FIL) is completely removed to sufficiently expose the active region 100 to the outside.

When the filling region (FIL) is not completely removed, the contact region between the storage-node pad region 530 formed in a subsequent process and the active region 100 may be reduced, which may decrease the reliability of the semiconductor device 1. Therefore, the portion of the filling region (FIL) overlapping the position where the storage-node pad region

530 is to be formed needs to be completely removed (and may be completely removed in accordance with embodiments of the present disclosure).

FIG. 14E is a cross-sectional view illustrating an example structure of the semiconductor device 1 taken along the line D-D’ of FIG. 14A according to an embodiment of the present disclosure.

FIG. 14F is a cross-sectional view illustrating an example structure of the semiconductor device 1 taken along the line E-E’ of FIG. 14A according to an embodiment of the present disclosure.

The cross-section of FIG. 14E may be substantially the same as the cross-section of FIG. 13E.

FIG. 14F shows that the portion which was the filling region (FIL) in FIG. 13F has been completely removed to form the second removal region (DEL2).

The following embodiments of FIGS. 15A to 15F will hereinafter be described with a focus on the characteristics that are different from those of FIGS. 14A to 14F.

FIG. 15A is a plan view illustrating an example result of performing operation S60 of FIG. 9 according to an embodiment of the present disclosure.

Referring to FIGS. 2, 3, 9, and 15A to 15F, the present manufacturing method may include forming a plurality of storage-node pad regions 530 formed between the pad insulation regions 700.

Referring to FIGS. 14A and 15A, the storage-node pad region 530 may be formed to gap-fill the second removal region (DEL2). The storage-node pad region 530 may, for example, include monocrystalline silicon that does not contain impurities. In some embodiments, after forming the storage-node pad region 530 that fills the second removal region (DEL2), a planarization process may be further performed. The storage-node pad

region 530 may extend in the second direction (Y). The storage-node pad regions 530 may be arranged to be spaced apart from each other repeatedly in the first direction (X).

FIG. 15B is a cross-sectional view illustrating an example structure of the semiconductor device 1 taken along the line A-A’ of FIG. 15A according to an embodiment of the present disclosure.

FIG. 15C is a cross-sectional view illustrating an example structure of the semiconductor device 1 taken along the line B-B’ of FIG. 15A according to an embodiment of the present disclosure.

FIG. 15D is a cross-sectional view illustrating an example structure of the semiconductor device 1 taken along the line C-C’ of FIG. 15A according to an embodiment of the present disclosure.

Referring to FIGS. 14A, 15A, and 15B, the storage-node pad region 530 may be disposed over the active region 100. The storage-node pad region 530 may be formed at an end opposite to the bitline pad region 430. The storage-node pad region 530 may be electrically and physically separated from the bitline pad region 430 by the pad insulation region 700.

The bitline pad region 430 may be disposed over one end of the active region 100 (e.g., the left end in FIG. 15B). The storage-node pad region 530 may be disposed over the other end (e.g., the right end in FIG. 15B) of the active region 100. The pad insulation region 700 may be disposed between the bitline pad region 430 and the storage-node pad region 530. The pad insulation region 700 may be disposed over the center of the active region 100.

The bitline pad region 430 may be disposed between two adjacent pad insulation regions 700. The storage-node pad region 530 may also be disposed between two adjacent pad insulation regions 700. The bitline pad region 430 and the storage-node pad region 530

may be alternately and repeatedly arranged in the first direction (X).

FIG. 15E is a cross-sectional view illustrating an example structure of the semiconductor device 1 taken along the line D-D’ of FIG. 15A according to an embodiment of the present disclosure.

The cross-section of FIG. 15E may be substantially the same as the cross-section of FIG. 14E.

FIG. 15F is a cross-sectional view illustrating an example structure of the semiconductor device 1 taken along the line E-E’ of FIG. 15A according to an embodiment of the present disclosure.

FIG. 15F may correspond to a cross-section in which the storage-node pad region 530 is formed in the second removal region (DEL2) of FIG. 14F.

The following embodiments of FIGS. 16A to 16F will hereinafter be described with a focus on the characteristics that are different from those of FIGS. 15A to 15F.

FIG. 16A is a plan view illustrating an example result of performing operation S70 of FIG. 9 according to an embodiment of the present disclosure.

Referring to FIGS. 2, 3, 9, and 16A to 16F, the present manufacturing method may include forming the plurality of wordline structures 300 (S70).

Referring to FIGS. 9, 10A, 15A, and 16A, the wordline structures 300 may be formed to extend in the first direction (X). The wordline structures 300 may be formed so as to penetrate the bitline pad regions 430 and the storage-node pad regions 530 shown in FIG. 15A.

In the present embodiment, the remaining bitline pad regions 430 after patterning may overlap one end of each active region 100 and may be electrically and physically separated not only from the storage-node pad regions 530 of other active regions 100 adjacent to each other in the first direction (X) but also from the bitline pad regions 430 of other active regions 100

adjacent to each other in the second direction (Y).

Each of the plurality of bitline pad regions 430 may overlap one end of the active region 100, and the plurality of bitline pad regions 430 may be repeatedly spaced apart from each other not only in the first direction (X) but also in the second direction (Y).

In some embodiments, each of the remaining storage-node pad regions 530 after patterning may overlap the other end of the active region 100, and may be electrically and physically separated not only from the bitline pad regions 430 of active regions 100 adjacent to each other in the first direction (X) but also from the storage-node pad regions 530 of other active regions 100 adjacent to each other in the second direction (Y).

Each of the plurality of storage-node pad regions 530 may overlap the other end of the active region, and the plurality of storage-node pad regions 530 may be repeatedly spaced apart from each other not only in the first direction (X) but also in the second direction (Y).

The wordline structures 300 may also be formed to pass through the pad insulation regions 700 as illustrated in FIG. 15A. Accordingly, the plurality of pad insulation regions 700 may be repeatedly spaced apart from each other not only in the first direction (X) but also in the second direction (Y).

FIG. 16B is a cross-sectional view illustrating an example structure of the semiconductor device 1 taken along the line A-A’ of FIG. 16A according to an embodiment of the present disclosure.

FIG. 16C is a cross-sectional view illustrating an example structure of the semiconductor device 1 taken along the line B-B’ of FIG. 16A according to an embodiment of the present disclosure.

Referring to FIGS. 15A, 16A, 16B, and 16C, a wordline trench (WT) extending in the third direction (Z) from the plane where the top surfaces of the bitline pad regions 430 and the

top surfaces of the storage-node pad regions 530 are located may be formed.

In the present disclosure, the height of the cell isolation region 200 recessed from the surface of the semiconductor layer (SL) in the third direction (Z) may be defined as a first height (H1), the height at which each of the bitline pad region 430, the storage-node pad region 530, and the pad insulation region 700 disposed above the surface of the semiconductor layer (SL) is formed may be defined as a second height (H2), and the height of the wordline trench (WT) recessed from the top surface of the bitline pad region 430 may be defined as a third height (H3).

As described above, the first height (H1) may, for example, be equal to or greater than 1600 Å and equal to or less than 1900 Å. As described above, the third height (H3) may, for example, be equal to or greater than 1000 Å and equal to or less than 1300 Å. The second height (H2) may, for example, be equal to or greater than 200 Å and equal to or less than 400 Å.

In order to guarantee reliable electrical isolation between adjacent active regions 100, it is necessary to secure a height difference between the bottom surface of the wordline trench (WT) and the bottom surface of the cell isolation region 200 and this may be implemented in accordance with the embodiments.

When the bitline contact region or the storage node contact region is disposed over the semiconductor layer surface (SL) without forming the bitline pad region 430, the storage-node pad region 530, and the pad insulation region 700, the first height (H1) may need to be relatively larger in order to ensure reliable electrical isolation between adjacent active regions 100.

However, when each of the bitline pad region 430, the storage-node pad region 530, and the pad insulation region 700 is formed to a second height (H2), the wordline trench (WT) is recessed in the third direction (Z) from the top surface of the bitline pad region 430.

Accordingly, a height difference between the bottom surface of the cell isolation region 200 and the bottom surface of the wordline trench (WT) may be denoted by “(H1+H2) − H3” rather than “(H1 – H3)”. In addition, even when the first height (H1) is set to a relatively low height, the adjacent active regions 100 may also be electrically isolated from each other. When the first height (H1) is set to a relatively low height, the additional effect of reducing the difficulty of the etching process used to form the cell isolation region 200 can be obtained.

After the wordline trench (WT) is formed, a wordline insulation layer 340 extending in the first direction (X) may be formed to contact the bottom and side surfaces of the wordline trench (WT). Subsequently, a first wordline electrode layer 310 extending in the first direction (X) may be formed over the wordline insulation layer 340. Thereafter, a second wordline electrode layer 320 extending in the first direction (X) may be formed over the first wordline electrode layer 310.

As illustrated in FIGS. 16B and 16C, an example is shown in which the surface of the semiconductor layer (SL) is located above the top surface of the first wordline electrode layer 310 and below the top surface of the second wordline electrode layer 320, but the scope of the present disclosure is not limited thereto. For example, the top surface of the second wordline electrode layer 320 may also be located below the surface of the semiconductor layer (SL).

FIG. 16D is a cross-sectional view illustrating an example structure of the semiconductor device 1 taken along the line C-C’ of FIG. 16A according to an embodiment of the present disclosure.

The cross-section of FIG. 16D may be substantially the same as the cross-section of FIG. 15D.

FIG. 16E is a cross-sectional view illustrating an example structure of the semiconductor device 1 taken along the line D-D’ of FIG. 16A according to an embodiment of

the present disclosure.

Referring to FIGS. 15A, 16A, and 16E, the plurality of wordline structures 300 may be repeatedly spaced apart from each other in the second direction (Y).

In addition, one side of each wordline structure 300 may contact the bitline pad region 430 that is in contact with the active region 100 contacting the bottom and side surfaces of the wordline structure 300.

FIG. 16F is a cross-sectional view illustrating an example structure of the semiconductor device 1 taken along the line E-E’ of FIG. 16A according to an embodiment of the present disclosure.

Referring to FIGS. 15A, 16A, and 16F, the plurality of wordline structures 300 may be repeatedly spaced apart from each other in the second direction (Y). One side of the wordline structure 300 may contact the storage-node pad region 530 contacting the active region 100 that is in contact with the bottom and side surfaces of the wordline structure 300.

The following embodiments of FIGS. 17A to 17F will hereinafter be described with a focus on the characteristics that are different from those of FIGS. 16A to 16F.

FIG. 17A is a plan view illustrating an example result of performing operation S80 of FIG. 9 according to an embodiment of the present disclosure.

Referring to FIGS. 2, 3, 9, and 17A to 17F, the present manufacturing method may include forming the plurality of bitline electrode layers 410, the plurality of bitline spacers 420, the plurality of bitline contact regions 440, and the plurality of bitline capping layers 450 (S80).

FIG. 17B is a cross-sectional view illustrating an example structure of the semiconductor device 1 taken along the line A-A’ of FIG. 17A according to an embodiment of the present disclosure.

Referring to FIGS. 9, 10A, 17A, and 17B, the bitline contact region 440 may be formed

to contact the top surface of the bitline pad region 430. Thereafter, the bitline electrode layer 410 disposed over the bitline contact region 440 may be formed. The bitline electrode layer 410 may be formed to extend in the second direction (Y). Thereafter, the bitline capping layer 450 disposed over the bitline electrode layer 410 may be formed. The bitline spacers 420 may be formed to contact both sides of each of the bitline electrode layer 410, the bitline contact region 440, and the bitline capping layer 450.

FIG. 17C is a cross-sectional view illustrating an example structure of the semiconductor device 1 taken along the line B-B’ of FIG. 17A according to an embodiment of the present disclosure.

Referring to FIGS. 9, 10A, 17A, and 17C, the plurality of bitline contact regions 440 may be formed spaced apart from each other in the first direction (X). The plurality of bitline electrode layers 410 may be formed spaced apart from each other in the first direction (X). The plurality of bitline capping layers 450 may be formed spaced apart from each other in the first direction (X). The plurality of bitline spacers 420 may laterally contact the bitline electrode layer 410 in the first direction (X), and may laterally contact the bitline electrode layer 410 in a direction opposite to the first direction (X).

Referring to FIGS. 17B and 17C, in a process of forming the bitline structure 400, the bitline spacers 420 may be formed to surround both side surfaces of the bitline electrode layer 410, or the space between the bitline electrode layers 410 adjacent to each other in the first direction (X) may be filled with an insulative material, and the bitline spacers 420 may be formed by etching a portion corresponding to a position where the storage-node contact region 540 is to be formed.

In the present disclosure, an example of the manufacturing method in which a portion corresponding to a position where the storage-node contact region 540 is to be formed is etched

to form the bitline spacer 420 will be described with reference to the attached drawings.

FIG. 17D is a cross-sectional view illustrating an example structure of the semiconductor device 1 taken along the line C-C’ of FIG. 17A according to an embodiment of the present disclosure.

Referring to FIGS. 9, 10A, 17A, and 17D, the bitline spacer 420 may be disposed over the pad insulation region 700. The plurality of bitline structures 400 may be arranged repeatedly spaced apart (for example, disposed in a configuration spaced apart) from each other in the first direction (X).

FIG. 17E is a cross-sectional view illustrating an example structure of the semiconductor device 1 taken along the line D-D’ of FIG. 17A according to an embodiment of the present disclosure.

Referring to FIGS. 9, 10A, 17A, and 17E, each of the bitline contact region 440, the bitline electrode layer 410, the bitline capping layer 450, and the bitline spacer 420 may be formed to extend in the second direction (Y).

FIG. 17F is a cross-sectional view illustrating an example structure of the semiconductor device 1 taken along the line E-E’ of FIG. 17A according to an embodiment of the present disclosure.

FIG. 17F is substantially the same cross-section as FIG. 16F.

The following embodiments of FIGS. 18A to 18F will hereinafter be described with a focus on the characteristics that are different from those of FIGS. 17A to 17F.

FIG. 18A is a plan view illustrating an example result of performing operation S90 of FIG. 9 according to an embodiment of the present disclosure.

Referring to FIGS. 2, 3, 9, and 18A to 18F, the present manufacturing method may include forming the plurality of storage-node contact regions 540 and the plurality of contact

insulation regions 600 (S90).

FIG. 18B is a cross-sectional view illustrating an example structure of the semiconductor device 1 taken along the line A-A’ of FIG. 18A according to an embodiment of the present disclosure.

Referring to FIGS. 9, 10A, 18A, and 18B, each of the plurality of storage-node contact regions 540 may be formed to overlap some parts of the active regions 100. One end of the active region 100 may be formed to overlap the bitline pad region 430. The other end of the active region 100 may be formed to overlap the storage-node contact regions 540. Each of the storage-node contact regions 540 may contact the top surface of the storage-node pad region 530. Each of the storage-node contact regions 540 may contact the top surface of the pad insulation region 700.

The storage-node contact region 540 may be formed after shallowly performing an additional etching at the portion where the storage-node contact region 540 is to be formed, so as to ensure complete contact with the storage-node pad region 530. If the top surface of the storage-node pad region 530 is fully exposed to the outside, the storage-node contact region 540 may be formed without additional etching. In this case, the bottom surface of the storage-node contact region 540 may be located on a plane substantially the same as the bottom surface of the bitline contact region 440.

FIG. 18C is a cross-sectional view illustrating an example structure of the semiconductor device 1 taken along the line B-B’ of FIG. 18A according to an embodiment of the present disclosure.

Referring to FIG. 18C, the plurality of contact insulation regions 600 may be disposed between the bitline spacers 420. For example, the contact insulation regions 600 may contact the bitline spacers 420 in the first direction (X). The contact insulation regions 600 may

contact the bitline spacers 420 in a direction opposite to the first direction (X).

Like the storage-node contact region 540, the contact insulation region 600 may be formed in a portion that has been etched simultaneously when some parts where the storage node contact region 540 is to be formed are shallowly additionally etched. In this case, the bottom surface of the contact insulation region 600 may be located lower than the bottom surface of the bitline spacer 420.

FIG. 18D is a cross-sectional view illustrating an example structure of the semiconductor device taken along the line C-C’ of FIG. 18A according to an embodiment of the present disclosure.

Referring to FIG. 18D, the plurality of storage-node contact regions 540 may be disposed between the bitline spacers 420. For example, the storage-node contact regions 540 may contact the bitline spacers 420 in the first direction (X). The storage-node contact regions 540 may contact the bitline spacers 420 in a direction opposite to the first direction (X).

FIG. 18E is a cross-sectional view illustrating an example structure of the semiconductor device 1 taken along the line D-D’ of FIG. 18A according to an embodiment of the present disclosure.

FIG. 18E may be substantially the same cross-section as FIG. 17E.

FIG. 18F is a cross-sectional view illustrating an example structure of the semiconductor device 1 taken along the line E-E’ of FIG. 18A according to an embodiment of the present disclosure.

Referring to FIG. 18F, the plurality of storage-node contact regions 540 and the plurality of contact insulation regions 600 may be alternately and repeatedly formed in the second direction (Y). Two side surfaces of each of the plurality of storage-node contact regions 540 may contact the contact insulation region 600. Two side surfaces of each of the

plurality of contact insulation regions 600 may contact the storage-node contact regions 540. For example, the storage-node contact regions 540 may contact the contact insulation regions 600 in the second direction (Y). The storage-node contact regions 540 may contact the contact insulation regions 600 in a direction opposite to the second direction (Y). In addition, the contact insulation regions 600 may contact the storage-node contact regions 540 in the second direction (Y). The contact insulation regions 600 may contact the storage-node contact regions 540 in a direction opposite to the second direction (Y).

As is apparent from the above description, the embodiments of the present disclosure may provide a semiconductor device in which the bridge phenomenon that may occur between adjacent active regions is prevented.

The embodiments of the present disclosure may provide a semiconductor device with improved operating speed and reduced leakage.

The embodiments of the present disclosure may provide a semiconductor device in which process complexity is reduced by forming a relatively shallow cell isolation region for defining active regions.

The embodiments of the present disclosure may provide a variety of effects capable of being directly or indirectly recognized.

Those skilled in the art will appreciate that the present disclosure may be carried out in other specific ways than those set forth herein. In addition, claims that are not explicitly presented in the appended claims may be presented in combination as an embodiment or included as a new claim by a subsequent amendment after the application is filed.

Although a number of illustrative embodiments have been described, it should be understood that modifications and enhancements to the disclosed embodiments and other embodiments can be devised based on what is described and/or illustrated in the present

disclosure.

What is claimed is:

1. A semiconductor device comprising:
a plurality of wordline structures disposed to extend in a first direction and configured to be spaced apart from each other in a second direction;
a plurality of active regions disposed to extend in a diagonal direction forming an acute angle with the first direction, configured to overlap the plurality of wordline structures, and configured to be spaced apart from each other in the first direction;
a plurality of bitline pad regions, each of which overlaps one end of a corresponding one of the plurality of active regions, contacts one side of a corresponding one of the plurality of wordline structures, and includes a first material;
a plurality of storage-node pad regions, each of which overlaps another end of the corresponding one of the plurality of active regions, contacts another side of the corresponding one of the plurality of wordline structures, and includes a second material different from the first material; and
a plurality of pad insulation regions, each of which is disposed between a corresponding one of the plurality of bitline pad regions and each of the plurality of storage-node pad regions, which are spaced apart from each other in the first direction.

2. The semiconductor device according to claim 1, wherein concentration of impurities included in the first material is higher than concentration of impurities included in the second material.

3. The semiconductor device according to claim 1, wherein:
the first material is polysilicon including impurities; and
the second material is monocrystalline silicon.

4. The semiconductor device according to claim 1, wherein:
a height of each of the plurality of bitline pad regions is equal to a height of each of the plurality of storage-node pad regions; and
a height of each of the plurality of bitline pad regions is equal to a height of each of the plurality of pad insulation regions.

5. The semiconductor device according to claim 1, wherein each of the plurality of bitline pad regions, each of the plurality of storage-node pad regions, and each of the plurality of pad insulation regions are disposed over a same plane as surfaces of the plurality of active regions.

6. The semiconductor device according to claim 1, wherein:
the second direction is perpendicular to the first direction; and
the second direction forms an acute angle with the diagonal direction.

7. The semiconductor device according to claim 1, wherein an angle formed between the diagonal direction and the first direction is in a range of 30 degrees to 60 degrees.

8. The semiconductor device according to claim 1, further comprising:
a plurality of bitline contact regions, each of which contacts a top surface of a corresponding one of the plurality of bitline pad regions;
a plurality of bitline electrode layers, each of which is disposed over a corresponding one of the plurality of bitline contact regions, overlaps a corresponding one of the plurality of bitline pad regions, and extends in the second direction;
a plurality of bitline spacers, each of which contacts both side surfaces of a corresponding one of the plurality of bitline electrode layers and extends in the second direction; and
a plurality of storage-node contact regions, each of which contacts a top surface of a corresponding one of the storage-node pad regions.

9. The semiconductor device according to claim 1, wherein the plurality of active regions is further arranged to be spaced apart from each other in the second direction, and to be spaced apart from each other in the diagonal direction.

10. The semiconductor device according to claim 9, wherein:
the plurality of bitline pad regions is arranged to be spaced apart from each other in the second direction; and
the plurality of storage-node pad regions is arranged to be spaced apart from each other in the second direction.

11. A method for manufacturing a semiconductor device, the method comprising:
forming a plurality of active regions that is repeatedly spaced apart from each other in a first direction and a second direction, extends in a diagonal direction with respect to the first direction, and is surrounded by a cell isolation region;
forming a plurality of first pad regions, each of which overlaps one end of a corresponding one of the plurality of active regions and extends in the second direction;
forming a plurality of pad insulation regions, each of which contacts both side surfaces of each of the plurality of first pad regions and extends in the second direction; and
forming a plurality of second pad regions that overlaps another end of the corresponding one of the plurality of active regions, extends in the second direction, and is spaced apart from the plurality of first pad regions.

12. The method according to claim 11, further comprising forming an active layer over the plurality of active regions and the cell isolation region,
wherein the forming the plurality of first pad regions includes removing a portion of the active layer.

13. The method according to claim 11, further comprising forming a plurality of filling regions between the plurality of first pad regions,
wherein the forming the plurality of pad insulation regions includes removing a portion of each of the plurality of filling regions.

14. The method according to claim 11, further comprising forming a plurality of wordline structures that overlaps centers of the plurality of active regions, extends in the first direction, and is repeatedly spaced apart from each other in the second direction.

15. The method according to claim 14, wherein the forming the plurality of wordline structures includes cutting a portion of each of the plurality of first pad regions, a portion of each of the plurality of second pad regions, and a portion of each of the plurality of pad insulation regions.

16. The method according to claim 14, further comprising:
forming a plurality of bitline electrode layers that overlaps the plurality of first pad regions and extends in the second direction; and
forming a plurality of storage-node contact regions that overlaps the plurality of second pad regions.

17. The method according to claim 16, further comprising:
forming a plurality of bitline contact regions, each of which is disposed between a corresponding one of the plurality of bitline electrode layers and a corresponding one of the plurality of first pad regions;
forming a plurality of bitline spacers, each of which contacts both side surfaces of each of the plurality of bitline electrode layers and extends in the second direction;
forming a plurality of bitline capping layers, each of which contacts a top surface of a corresponding one of the plurality of bitline electrode layers; and
forming a plurality of contact insulation regions, each of which is disposed between the plurality of storage-node contact regions adjacent to each other in the second direction.
